(19) United States
(12) Patent Application Publication
(10) Pub. No.: US 2021/0286051 A1
(43) Pub. Date: Sep. 16, 2021

(54) DISTANCE MEASURING DEVICE, AND TIME MEASUREMENT METHOD BASED ON DISTANCE MEASURING DEVICE

(71) Applicant: SZ DJI TECHNOLOGY CO., LTD., Shenzhen (CN)

(72) Inventors: Xiang LIU, Shenzhen (CN); Xiaoping HONG, Shenzhen (CN)

(21) Appl. No.: 17/214,709

(22) Filed: Mar. 26, 2021

Related U.S. Application Data
(63) Continuation of application No. PCT/CN2018/108149, filed on Sep. 27, 2018.

(51) Int. Cl. G01S 7/489; H03F 3/45; H03F 1/52; G01S 7/484; G01S 7/481; G01S 17/10

(52) U.S. Cl. CPC G01S 7/489; H03F 3/45475; G01S 17/10; G01S 7/484; G01S 7/4817; H03F 1/52

(57) ABSTRACT

Embodiments of the present disclosure provide an amplification circuit. The amplification circuit includes an operational amplifier; and a clamping circuit being respectively connected to an input terminal and an output terminal of the operational amplifier for clamping an input signal of the amplification circuit to cause the input signal of the amplification circuit to fluctuate within a certain range to prevent the operational amplifier from generating a saturating output.

### CROSS-REFERENCE TO RELATED APPLICATION

This application is a continuation of International Application No. PCT/CN2018/108149, filed on Sep. 27, 2018, the entire content of which is incorporated herein by reference.

### TECHNICAL FIELD

The present disclosure relates to the technical field of distance measuring devices and, more specifically, to a distance measuring device, a time measurement method based on the distance measuring device.

### BACKGROUND

A distance measuring device is a radar system that emits a laser beam to detect the location and speed of a target. The photosensitive sensor of the distance measuring device can convert the obtained light pulse signal into an electrical signal, and obtain the time information corresponding to the electrical signal based on a comparator, thereby obtaining the distance information between the distance measuring device and the target.

However, the working environment of the distance measuring device can be complicated, the intensity of the electrical signal obtained by the device can have a relatively large fluctuation range, and the noise signal included in the electrical signal can also be strong or weak. Based on how the comparator collects time information, the voltage threshold is fixed, and the noise signal included in the electrical signals with relative large fluctuation can trigger the comparator and cause distortion of the measured time information. Even if the voltage threshold is adjusted during use, it is difficult to adjust the threshold when the sampling speed of the system is high.

### SUMMARY

One aspect of the present disclosure provides an amplification circuit. The amplification circuit includes an operational amplifier; and a clamping circuit being respectively connected to an input terminal and an output terminal of the operational amplifier for clamping an input signal of the amplification circuit to cause the input signal of the amplification circuit to fluctuate within a certain range to prevent the operational amplifier from generating a saturating output.

Another aspect of the present disclosure provides a distance detection device. The device includes a transmitting circuit configured to emit a light pulse sequence; a photoelectric conversion circuit configured to sequentially receive a plurality of light pulse signals of a plurality of light pulses in the light pulse sequence transmitted by the transmitting circuit reflected by an object, and sequentially convert the plurality of received light pulse signals into a plurality of electrical pulse signals; and an amplification circuit configured to receive the plurality of electrical pulse signals from the photoelectric conversion circuit, the operational amplifier including an operational amplifier and a clamping circuit, the clamping circuit being configured to sequentially clamp the plurality of electrical pulse signals. The plurality of electrical pulse signals are sequentially input to the operational amplifier for amplification after being clamped, and the clamping circuit is configured to cause fluctuation of the plurality of electrical pulse signals to be within a certain range to prevent the operational amplifier from generating a saturating output.

### BRIEF DESCRIPTION OF THE DRAWINGS

In order to illustrate the technical solutions in accordance with the embodiments of the present disclosure more clearly, the accompanying drawings to be used for describing the embodiments are introduced briefly in the following. It is apparent that the accompanying drawings in the following description are only some embodiments of the present disclosure. Persons of ordinary skill in the art can obtain other accompanying drawings in accordance with the accompanying drawings without any creative efforts.

FIG. 1 is a schematic diagram of a distance measuring device according to an embodiment of the present disclosure.

FIG. 2A is a schematic diagram of another distance measuring device according to an embodiment of the present disclosure.

FIG. 2B is a schematic diagram of another distance measuring device according to an embodiment of the present disclosure.

FIG. 3 is a schematic diagram of a first principle of preventing a noise signal from triggering a comparator circuit according to an embodiment of the present disclosure.

FIG. 4 is a schematic diagram of a second principle of preventing a noise signal from triggering a comparator circuit according to an embodiment of the present disclosure.

FIG. 5 is a schematic diagram of a principle of a time extraction method according to an embodiment of the present disclosure.

FIG. 6 is a schematic circuit diagram of a first implementation method of adjusting a preset threshold according to an embodiment of the present disclosure.

FIG. 7 is a schematic circuit diagram of a second implementation method of adjusting the preset threshold according to an embodiment of the present disclosure.

FIG. 8 is a schematic diagram of another distance measuring device according to an embodiment of the present disclosure.

FIG. 9 is a schematic circuit diagram of an adjustment circuit of an avalanche photodiode (APD) gain according to an embodiment of the present disclosure.

FIG. 10 is a flowchart of a time measurement method based on the distance measuring device according to an embodiment of the present disclosure.

FIG. 11 is a flowchart of another time measurement method based on the distance measuring device according to an embodiment of the present disclosure.

FIG. 12 is a schematic diagram of a principle of another time extraction method according to an embodiment of the present disclosure.

FIG. 13 is a schematic diagram of another distance measuring device according to an embodiment of the present disclosure.

FIG. 14 is a schematic diagram of a connection method of a laser transmitting device in conventional technology.

FIG. 15A is a first structural diagram of a laser transmitting device according to an embodiment of the present disclosure.

FIG. 15B is the first structural diagram of the laser transmitting device according to an embodiment of the present disclosure.

FIG. 16 is a second structural diagram of the laser transmitting device according to an embodiment of the present disclosure.

FIG. 17 is a third structural diagram of the laser transmitting device according to an embodiment of the present disclosure.

FIG. 18 is a first structural diagram of a charging circuit according to an embodiment of the present disclosure.

FIG. 19 is a second structural diagram of the charging circuit according to an embodiment of the present disclosure.

FIG. 20 is a partial structural diagram of a storage circuit according to an embodiment of the present disclosure.

FIGS. 21A and 21B are schematic wiring diagrams of a first type of component failure or short circuit according to an embodiment of the present disclosure.

FIGS. 22A and 22B are schematic wiring diagrams of a second type of component failure or short circuit according to an embodiment of the present disclosure.

FIGS. 23A and 23B are schematic wiring diagrams of a third type of component failure or short circuit according to an embodiment of the present disclosure.

FIG. 24 is a schematic wiring diagram of a fourth type of component failure or short circuit according to an embodiment of the present disclosure.

FIGS. 25A and 25B are schematic wirings diagram of a fifth type of component failure or short circuit according to an embodiment of the present disclosure.

FIGS. 26A and 26B are schematic wiring diagrams of a sixth type of component failure or short circuit according to an embodiment of the present disclosure.

FIGS. 27A and 27B are schematic wiring diagrams of a seventh type of component failure or short circuit according to an embodiment of the present disclosure.

FIGS. 28A and 28B are schematic wiring diagrams of an eighth type of component failure or short circuit according to an embodiment of the present disclosure.

FIG. 29 is a schematic block diagram of the laser transmitting device according to an embodiment of the present disclosure.

FIG. 30 is a schematic wiring diagram of a self-check circuit according to an embodiment of the present disclosure.

FIG. 31 is a schematic diagram of waveforms before and after filtering in the self-check circuit according to an embodiment of the present disclosure.

FIG. 32 is a schematic diagram of waveforms before and after amplification in the self-check circuit according to an embodiment of the present disclosure.

FIG. 33 is a first wiring diagram of a peak hold circuit according to an embodiment of the present disclosure.

FIG. 34 is a second wiring diagram of the peak hold circuit according to an embodiment of the present disclosure.

FIG. 35 is a signal waveform of a positive and negative input terminals of an operational amplifier according to an embodiment of the present disclosure.

FIG. 36 is a schematic diagram of an amplification circuit according to an embodiment of the present disclosure.

FIG. 37 is a first wiring diagram of the amplification circuit according to an embodiment of the present disclosure.

FIG. 38 is a second wiring diagram of the amplification circuit according to an embodiment of the present disclosure.

FIG. 39 is a third wiring diagram of the amplification circuit according to an embodiment of the present disclosure.

FIG. 40 is a fourth wiring diagram of the amplification circuit according to an embodiment of the present disclosure.

FIG. 41 is an effect diagram of a first clamping module before and after clamping according to an embodiment of the present disclosure.

FIG. 42 is a fifth wiring diagram of the amplification circuit according to an embodiment of the present disclosure.

FIG. 43 is a sixth wiring diagram of the amplification circuit according to an embodiment of the present disclosure.

FIG. 44 is a seventh wiring diagram of the amplification circuit according to an embodiment of the present disclosure.

FIG. 45 is an effect diagram of a third clamping module before and after clamping according to an embodiment of the present disclosure.

FIG. 46 is an eighth wiring diagram of the amplification circuit according to an embodiment of the present disclosure.

FIG. 47 is a wiring diagram of the clamping circuit of the amplification circuit according to an embodiment of the present disclosure.

### DETAILED DESCRIPTION OF THE EMBODIMENTS

Technical solutions of the present disclosure will be described in detail with reference to the drawings. It will be appreciated that the described embodiments represent some, rather than all, of the embodiments of the present disclosure. Other embodiments conceived or derived by those having ordinary skills in the art based on the described embodiments without inventive efforts should fall within the scope of the present disclosure.

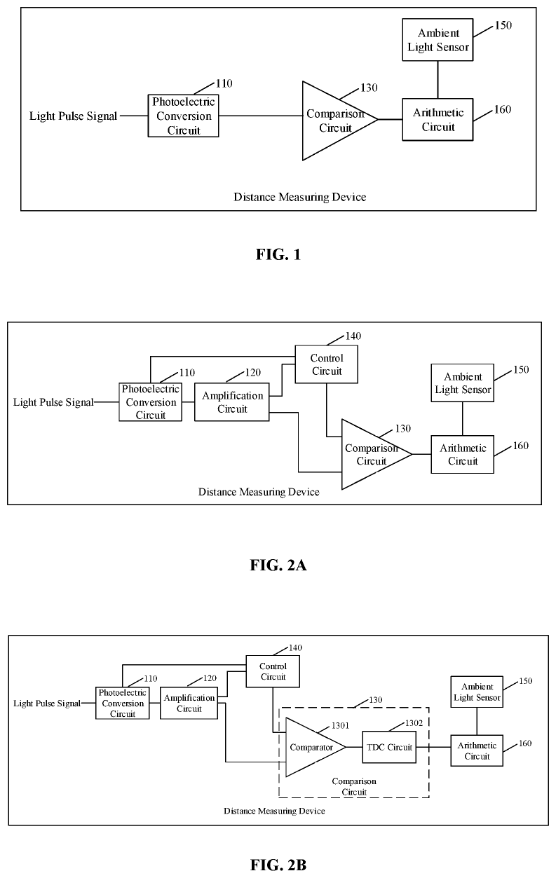

FIG. 1 is a schematic diagram of a distance measuring device according to an embodiment of the present disclosure. The distance measuring device includes at least an ambient light sensor 150, a comparison circuit 130, and an arithmetic circuit 160. In some embodiments, a plurality of preset thresholds may be set in parallel in the comparison circuit 130.

In some embodiments, the distance measuring device may also include a photoelectric conversion circuit 110. One end of the conversion circuit 110 can be connected to the comparison circuit 130, an output end of the comparison circuit can be electrically connected to one end of the arithmetic circuit, and the other end of the arithmetic circuit can be electrically connected to the ambient light sensor.

In some embodiments, the comparison circuit can be used to receive the electrical signal obtained through optical signal processing, and extract the time information of the preset threshold triggered by the electrical signal.

In some embodiments, the ambient light sensor can be used to obtain the intensity of the ambient light signal in the period of time where the time information is located.

In some embodiments, the arithmetic circuit can be configured to select, from the time information of the triggered preset threshold, the time information of the preset threshold that is at least partially triggered based on the intensity of the ambient light signal, and perform calculations based on the selected time information.

In some embodiments, the arithmetic circuit can be used to determine the distance between an object and the distance measuring device based on the time information output by the comparison circuit.

In some embodiments, three or more preset thresholds can be set in parallel in the comparison circuit, such that in the subsequent process, the comparison circuit can compare the electrical signal with at least a part of the plurality of preset thresholds after receiving the electrical signal obtained through optical signal processing, then extract the time information of the preset threshold triggered by the electrical signal.

In some embodiments, the arithmetic circuit can be configured to use the intensity of the ambient light signal as a basis for determining whether the extracted time information is the time information corresponding to the valid light pulse signal, and to select the preset threshold for performing the calculation.

In some embodiments, the preset threshold to be selected for comparison may be determined based on the intensity of the ambient light signal. For example, when it is detected that the external ambient light is relatively weak, all preset thresholds may be selected for comparison, and then the time information of the preset threshold triggered by the electrical signal may be extracted. When it is detected that the external ambient light is relatively strong, some preset thresholds with smaller values may be turned off, and no comparison may be performed or the next calculation processing may not be performed. When the external light is relatively strong, the bottom threshold may trigger a certain amount of noise, but these data will not be calculated as signals, and the final point cloud output by the radar will not contain noise.

In some embodiments, the arithmetic circuit can be configured to compare the maximum preset threshold triggered by the electrical signal with the maximum preset threshold corresponding to the intensity of the ambient light signal; if the maximum preset threshold triggered by the electrical signal is not greater than the maximum preset threshold corresponding to the intensity of the ambient light signal, the optical signal may be a noise signal; and/or, if the maximum preset threshold triggered by the electrical signal is greater than the maximum preset threshold corresponding to the intensity of the ambient light signal, the optical signal may include a valid light pulse signal.

Further, if the maximum preset threshold triggered by the electrical signal is greater than the maximum preset threshold corresponding to the intensity of the ambient light signal, the arithmetic circuit may be used to at least select the time information when the preset threshold that is greater than the maximum preset threshold corresponding to the intensity of the ambient light signal is triggered.

As an example, if the maximum preset threshold triggered by the electrical signal is greater than the maximum preset threshold corresponding to the intensity of the ambient light signal, all preset thresholds may be compared with the electrical signal to extract the corresponding time information. In some embodiments, in all the extracted time information, the time information generated by the preset threshold greater than the maximum preset threshold corresponding to the intensity of the ambient light signal may be the time information generated by the valid electrical pulse signal, the time information generated by the preset threshold less than the maximum preset threshold corresponding to the intensity of the ambient light signal may be the time information generated by the superimposed signal of the valid electrical pulse signal and the environmental noise that triggers the preset threshold.

As an example, when the maximum preset threshold triggered by the electrical signal is greater than the maximum preset threshold corresponding to the intensity of the ambient light signal, in order to improve the efficiency of time information extraction, the arithmetic circuit can be used to discard a preset threshold less than the maximum preset threshold corresponding to the intensity of the ambient light signal without comparing it with the electrical signal. That is, the overlapping data of the time information generated by the valid electrical pulse signal and the time information generated by the environmental noise can be discarded, and the time information may not be output.

In subsequent calculations, the arithmetic circuit can be used to select all the time information for calculation, or select the time information triggered by a preset threshold greater than the maximum preset threshold corresponding to the intensity of the ambient light signal.

In some embodiments, another method for determining the time information as a valid electrical pulse signal or noise may include the following. The arithmetic circuit may be configured to compare the number of time information extracted by the comparison circuit and the number of thresholds that can be trigged by the intensity of the ambient light signal. If the number of time information extracted by the comparison circuit is not greater than the number of time information generated by the ambient light signal, the optical signal can be determined as a noise signal; and/or, if the number of time information extracted by the comparison circuit is greater than the number of time information generated by the ambient light signal, the optical signal may include a valid light pulse signal.

In one embodiment of the present disclosure, as shown in FIG. 2A, the distance measuring device further includes a control circuit 140. The control circuit 140 can be used to turn off the smaller part of the preset threshold based on the intensity of the ambient light signal output by the ambient light sensor. The implementation methods may include at least the following two methods.

In the first method, if the comparison circuit includes a comparator and a time-to-digital converter (TDC), the comparator and the TDC corresponding to the smaller part of the preset threshold may be turned off to achieve partial preset threshold shutdown.

In the second method, if the comparison circuit includes an ADC, the ADC corresponding to the smaller part of the preset threshold may be turned off to achieve partial preset threshold shutdown.

In one embodiment of the present disclosure, the comparison circuit 130 may include one or more comparators. Referring to FIG. 2B, which is a schematic diagram of another distance measuring device according to an embodiment of the present disclosure. As shown in FIG. 2B, a first input terminal of a comparator 1301 is used to receive the electrical signal input from an amplification circuit 120, that is, the electrical signal after the amplification operation, and a second input terminal of the comparator 1301 is used to receive a preset threshold, and the output terminal of the comparator 1301 is used to output a comparison result. In some embodiments, comparison result may include time information corresponding to the electrical signal. It can be understood that the preset threshold received by the second input terminal of the comparator 1301 may be an electrical signal whose strength is the preset threshold. The comparison result may be a digital signal corresponding to the electrical signal after the amplification operation.

In some embodiments, the comparison circuit 130 may further includes a TDC 1302. The TDC 1302 can be electrically connected to the output terminal of the comparator 1301, and the TDC 1302 can be configured to extract time information corresponding to the electrical signal based on the comparison result output by the comparator 1301.

As an example, when using a comparator to perform signal acquisition, in order to obtain more information, a multi-threshold comparison method can be used. The multi-threshold comparator collecting pulse signals may refer to the use of multiple comparators. Each comparator may use different voltage thresholds to obtain more information about the pulse signal.

The comparison circuit may include a plurality of comparators. The first input terminal of the comparator may be used to receive the electrical pulse signal, the second input terminal of the comparator may be used to receive the preset threshold, and the output terminal of the comparator may be used to output the comparison result. In some embodiments, the comparison result may include time information corresponding to the electrical signal.

In some embodiments, the comparison circuit may further include a TDC. The TDC may be electrically connected to the output terminal of the comparator, and configured to extract time information corresponding to the electrical signal based on the comparison result output by the comparator.

The comparison circuit may include a plurality of comparators and a plurality of TDCs. The comparators may be connected to the TDCs in a one-to-one correspondence, and the output terminals of the plurality of comparators may be respective electrically connected to the TDCs corresponding to each of the plurality of comparators. It should be noted that one TDC may also correspond to two or more comparators for extracting the time information corresponding to the electrical signals based on the comparison results output by the two or more comparators.

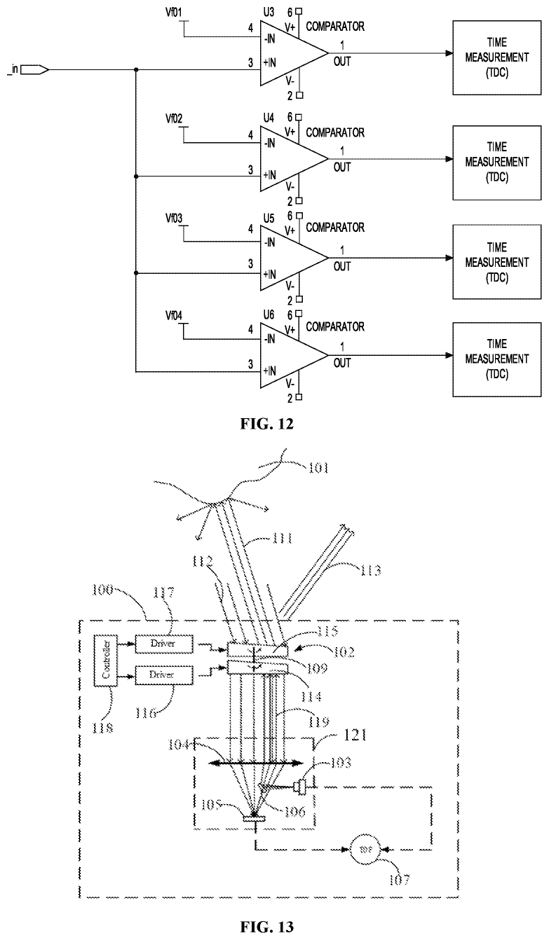

In one embodiment of the present disclosure, the four-threshold comparator acquisition circuit is taken as an example. As shown in FIG. 12, the four comparators are set with different thresholds, which are Vf01, Vf02, Vf03, and Vf04. The square wave signals output by the four comparators are respectively connected to the four TDC measuring units to obtain the threshold time information corresponding to the pulse signals.

In some embodiments, the distance measuring device may also include a photoelectric conversion circuit 110. The photoelectric conversion circuit 110 can be used to receive light pulse signals, converting the light pulse signals into electrical signals, and output the electrical signals. In some embodiments, the photoelectric conversion circuit 110 may be a photosensitive sensor, but it is not limited to a photosensitive sensor, and other elements that can realize the function of the present disclosure can be used in the distance measuring device, which will not be listed here.

The comparison circuit can be used to receive the electrical signal from the photoelectric conversion circuit. In some embodiments, the comparison circuit and the photoelectric conversion circuit may be directly connected, or there may be an amplification circuit between the two. For example, a first-level amplification circuit and a second-level amplification circuit can be arranged, and the electrical signal output by the photoelectric conversion circuit can be amplified in two stages and then input to the comparison circuit. In some embodiments, the amplification circuit may be directly connected to the comparison circuit, or there may be other processing circuits between the amplification circuit and the comparison circuit, which is not limited in the embodiments of the present disclosure.

For example, one end of the photoelectric conversion circuit 110 may be electrically connected to the first end of the amplification circuit 120, and the other end of the photoelectric conversion circuit 110 may be electrically connected to the control circuit 140. The second end of the amplification circuit 120 may be electrically connected to the comparison circuit 130 and the control circuit 140, respectively. The control circuit 140 may be electrically connected to the comparison circuit 130. The amplification circuit 120 may be configured to amplify the electrical signal input from the photoelectric conversion circuit 110 and output the amplified electrical signal to the comparison circuit 130.

In one embodiment of the present disclosure, the control circuit 140 may also be used to adjust the gain of the photoelectric conversion circuit 110, or adjust the preset threshold of the comparison circuit 130, such that the noise signal can be lower than the preset threshold.

It can be understood that the electrical signal can include noise, therefore, the amplified electrical signal can also include the noise signal. The distance measuring device described above can adjust the gain of the photoelectric conversion circuit 110 or adjust the preset threshold of the comparison circuit 130 to avoid distortion of the measured time information caused by the noise signal triggering the comparison circuit when the noise signal is greater than the preset threshold.

There are two methods to prevent the noise signal from triggering the comparison circuit 130. The first method may include adjusting the preset threshold of the comparison circuit, that is, the preset threshold of the comparator. The second method may include adjusting the intensity of the electrical signal by adjusting the gain of the photoelectric sensor (such as APD), such that the electrical signal input from the amplification circuit, that is, the intensity of the noise signal in the electrical signal after the amplification operation can be lower than the preset threshold.

In some embodiments, after the arithmetic circuit selects, from the time information of the triggered preset threshold, the time information of the preset threshold that is at least partially triggered based on the intensity of the ambient light signal, and perform calculations based on the selected time information, there may be no need to use the first method to adjust the preset threshold of the comparison circuit.

The following are detailed descriptions of the first method and the second method.

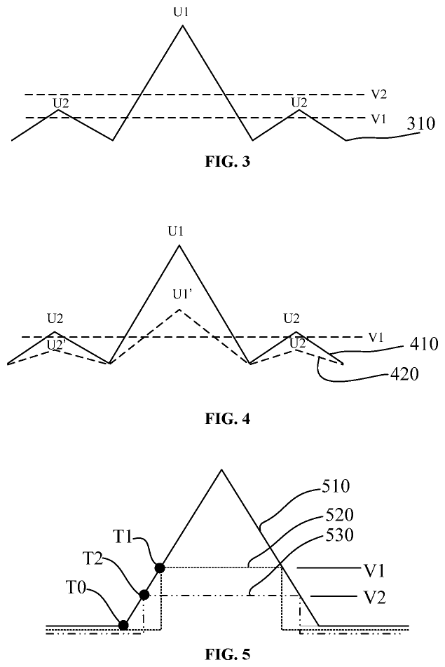

FIG. 3 is a schematic diagram of a first principle of preventing a noise signal from triggering a comparator circuit according to an embodiment of the present disclosure. The electrical signal 310 input to the first input terminal of the comparator includes an electrical pulse signal U1 and a noise signal U2. When the preset threshold is at a threshold V1, the intensity of the noise signal exceeds the threshold V1, and the noise signal triggers the comparator to output a high-level signal, resulting in distortion of the output signal of the comparator and further introduce errors in the extracted time information. At this point, the preset threshold can be increased. For example, if the preset threshold is adjusted to a threshold V2, the intensity of the noises signal is less than the threshold V1, thereby preventing the noise signal U2 from triggering the comparator.

In one embodiment of the present disclosure, in the first method to prevent the noise signal from triggering the preset threshold, the control circuit 140 may also be used to adjust the preset threshold based on the intensity of the noise signal such that the preset threshold can be less than the intensity of the noise signal. In this way, under the wide dynamic light pulse signal, the preset threshold of the comparison circuit can be dynamically adjusted based on the intensity of the noise signal in the amplified electrical signal.

FIG. 5 is a schematic diagram of a principle of a time extraction method according to an embodiment of the present disclosure. As shown in FIG. 5, an electrical signal 510 inputs to the comparison circuit is compared with the threshold V1 to obtain a first square wave signal 520 as shown by the dotted line. A time T1 of the transition edge of the first square wave signal 520 can be considered as the time when the electrical signal 510 passes through the comparator. Similarly, the electrical signal 510 inputs to the comparison circuit is compared with the threshold V2 to obtain a second square wave signal 530 as shown by the dotted line. A time T2 of the transition edge of the second square wave signal 530 can be considered as the time when the electrical signal 510 passes through the comparators, and T0 is the real time when the electrical signal 510 passes through the comparator. It can be seen that the smaller the preset threshold, the closer the transition edge time is to the real time when the amplified electrical signal passes through the comparator.

In some embodiments, the control circuit 140 may also be used to determine a preset threshold based on the strength of the noise signal, such that the preset threshold can be higher than the noise signal and the difference between the preset threshold and the maximum value of the noise signal may not be greater than the preset threshold, such as 0.1V, 0.2A, etc. As such, the distance measuring device can determine the most suitable preset threshold of the comparison circuit 130 based on the intensity of the noise signal. On the premise that the preset threshold is greater than the noise signal, the preset threshold can be reduce as much as possible, such that the time information extracted by the comparison circuit 130 may be closer to the real time when the electrical signal input from the amplification circuit passes through the comparison circuit 130, thereby avoiding errors in the collection of the time information caused by the change of signal amplitude, and the accuracy of the time measurement is high.

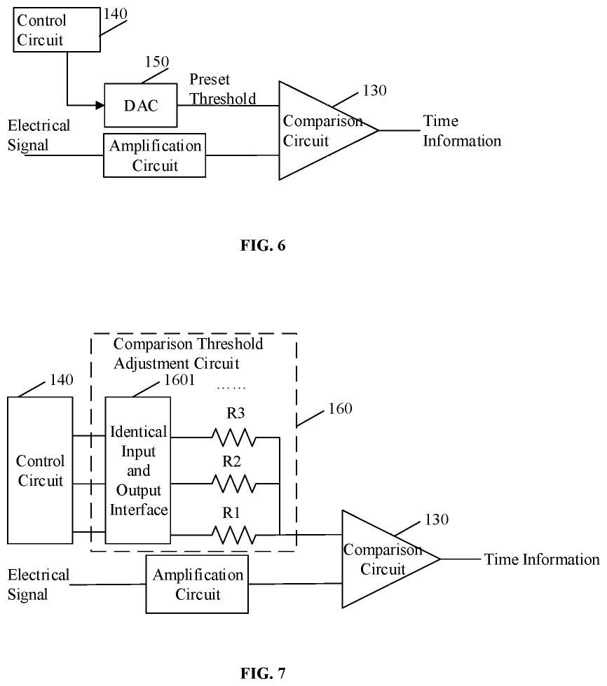

In one embodiment of the present disclosure, a first implementation method to adjust the preset threshold can be seen in FIG. 6. FIG. 6 is a schematic circuit diagram of a first implementation method of adjusting a preset threshold according to an embodiment of the present disclosure. As shown in FIG. 6, the distance measuring device further includes a digital-to-analog converter 150. The control circuit 140 can be connected to the second input terminal of the comparison circuit 130 through the digital-to-analog converter 150 and adjust the preset threshold of the comparison circuit by controlling the output voltage of the digital-to-analog converter 150.

In one embodiment of the present disclosure, in a second implementation method to adjust the preset threshold, the distance measuring device may further include a comparison threshold adjustment circuit 160. The comparison threshold adjustment circuit may include a plurality of resistors. One of end of plurality of resistors may be connected to the second input terminal of the comparator. A plurality of voltage signals may be input to the other end of the plurality of resistors for providing a preset threshold to the second input terminal of the comparator through the plurality of resistors. By adjusting the composition structure of the plurality of resistors, the preset threshold input to the second input terminal of the comparison circuit may be adjusted.

For example, referring to FIG. 7, which is a schematic circuit diagram of a second implementation method of adjusting the preset threshold according to an embodiment of the present disclosure. The comparison threshold adjustment circuit 160 includes a plurality of resistors, such as a first resistor R1, a second resistor R2, a third resistor R3, etc. The first ends of the first resistor R1, the second resistor R2, and the third resistor R3 are commonly connected to the second input terminal of the comparator 1301. The other ends of the first resistor R1, the second resistor R2, and the third resistor R3 are respectively connected to a plurality of identical input and output interface 1601 of the control circuit 140 in a one-to-one correspondence. The control circuit 140 can adjust the preset threshold of the comparison circuit 130 by controlling the outlet level of the plurality of identical input and output interface 1601.

FIG. 4 is a schematic diagram of a second principle of preventing a noise signal from triggering a comparator circuit according to an embodiment of the present disclosure. Ab electrical signal 410 shown by the solid line is the electrical signal input to the first input terminal of the comparator before adjusting the gain of the photosensitive sensor. The electrical signal 410 includes an electrical pulse signal U1 and a noise signal U2. When the preset threshold is the threshold V1, the intensity of the noise signal exceeds the threshold V1, and the noise signal triggers the comparator to output a high-level signal, resulting in distortion of the comparator output signal. At this time, the gain of the photosensitive sensor may be reduced. After the gain of the photosensitive sensor is reduced, the electrical signal (that is, the electrical signal 410 shown by the dotted line) input to the first input terminal of the comparator after adjusting the gain of the photosensitive sensor may have a lower ratio compared with the electrical signal 410, and the intensity of an electrical pulse signal U1′ and a noise signal U2′ in the electrical signal 420 may be reduced. As such, the intensity of the electrical pulse signal U1′ may be less than the threshold V1, thereby preventing the noise signal U2′ from triggering the comparator.

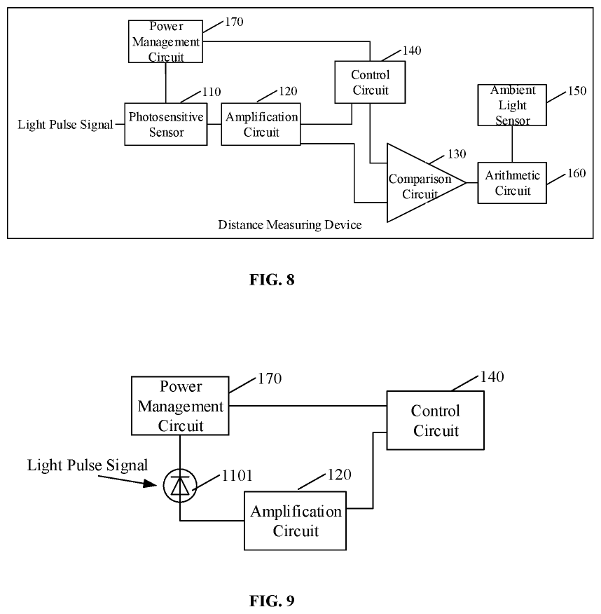

FIG. 8 is a schematic diagram of another distance measuring device according to an embodiment of the present disclosure. As shown in FIG. 8, the distance measuring device further includes a power management circuit 170, and the power management circuit 170 can be electrically connected to the control circuit 140 and the photoelectric conversion circuit 110. The power management circuit 170 can be used to provide a working voltage for the photoelectric conversion circuit 110, and the control circuit 140 can adjust the gain of the photoelectric conversion circuit 110 by controlling the power management circuit 170 to adjust the working voltage.

FIG. 9 is a schematic circuit diagram of an adjustment circuit of an avalanche photodiode (APD) gain according to an embodiment of the present disclosure. The photoelectric conversion circuit 110 includes an APD 1101. The cathode of the APD 1101 is electrically connected to the power management circuit 170 for obtaining the working voltage from the power management circuit 170. The anode of the APD 1101 is connected to the input terminal of the amplification circuit. The APD 1101 can be sued to receive the light pulse signal, convert the light pulse signal into an electrical signal, and output the electrical signal to the amplification circuit 120.

It can be understood that the greater the working voltage, the greater the gain of the APD, and the greater the light pulse signal and the noise obtained by the APD. In some embodiments, the control circuit 140 may also determine the working voltage of the photoelectric conversion circuit 110 based on the intensity of the noise signal. It can be understood that a strong noise signal may correspond to a lower working voltage, on the contrary, the first noise signal may correspond to a higher working voltage.

It should be noted that the distance measuring device may adopt either the first method or the second method to prevent the noise signal from triggering the preset threshold. It can be understood that the noise signal may include an electrical noise signal and an optical noise signal.

In the embodiments of the present disclosure, the control circuit 140 may also be used to obtain and compare the intensity of the optical noise signal and the intensity of the electrical noise signal. When the intensity of the optical noise signal is less than the intensity of the electrical noise signal, that is, when the electrical noise signal is dominant, the first method described above may be used to adjust the preset threshold of the comparison circuit 130, such that the noise signal can be lower than the preset threshold. When the intensity of the optical noise signal is greater than the intensity of the electrical noise signal, that is, when the optical noise is dominant, the second method described above may be used to adjust the gain of the photoelectric conversion circuit 110, such that the noise signal can be lower than the preset threshold.

It can be understood that for a given electronic device, the intensity of the electrical noise may be relatively stable, while the intensity of the optical noise may be greatly affected by the environment. The higher the optical intensity in the environment, the higher the intensity of the optical noise. Therefore, the intensity of the noise signal can be measured to indicate the intensity of the optical noise.

In some embodiments, for the TDC measurement method, it is ideal if the gain of the APD is stable or the gain of the APD is known. However, the gain of the APD is related to temperature, and there are relatively large differences between different APDs. In order to keep the gain stable, the APD can be calibrated. In some embodiments, the controller in the distance measuring device may also be used to obtain the current temperature and adjust the gain of the photosensitive sensor based on the current temperature.

In some embodiments, the controller may be further configured to determine a preset threshold based on the intensity of the noise signal, such that the preset threshold may be higher than the noise signal and the difference between the preset threshold and the maximum value of the noise signal may not be greater than the preset threshold.

Since the gain of the APD is related to temperature, in order to accurately control the gain of the APD, the gain, temperature, and voltage at different temperatures and voltages can be measured first, then the curves of the three may be obtained by calculation. In actual use, the difference from the embodiments described above may be that the corresponding relationship between the voltage and the gain of the photosensitive sensor at different temperatures may be pre-stored in the controller. The controller may first read the current temperature of the APD, and calculate the voltage under different gains through the calibration curve. Subsequently, through the control of the high-voltage power supply, the gain of the APD can be precisely controlled, thereby obtaining a balance between noise and protection.

As shown in FIG. 11, an embodiment of the present disclosure further provides a time measurement method based on a distance measuring device. The method will be described in detail below.

S2010, receiving a light pulse signal, and converting the light pulse signal into an electrical signal for output.

S2020, comparing the input electrical signal with a preset threshold, and extracting time information corresponding to the electrical signal.

S2030, obtaining a current temperature, and adjusting the gain of the photosensitive sensor based on the current temperature.

In this embodiment, the influence of temperature on the gain of the photosensitive sensor is taken into consideration when adjusting the gain of the photosensitive sensor, thereby achieving precise control of the gain of the APD and obtaining a balance between noise and protection.

In the embodiments of the present disclosure, when it is detected that the comparison circuit 130 is triggered by a noise signal, the control circuit 140 may also trigger the first method described above to adjust the preset threshold or the second method described above to adjust the gain of the photoelectric conversion circuit 110.

In some embodiments, the control circuit 140 can also be used to determine whether the noise signal is higher than a preset threshold. When the noise signal is higher than the preset threshold, the control circuit 140 may be triggered to adjust the gain of the photoelectric conversion circuit 110, or adjust the preset threshold of the comparison circuit 130. When the noise signal is less than or equal to the preset threshold, the control circuit 140 may not adjust the gain of the photoelectric conversion circuit 110 or the preset threshold of the comparison circuit 130.

A first implementation method for the control circuit 140 to determine whether the noise signal is higher than the preset threshold may include the control circuit 140 obtaining the number of random noise points in an initial image generated by the distance measuring device, and determining whether the number of random noise points is greater than a preset noise point threshold. The initial image may be an initial image generated by the control circuit 140 based on the electrical signal input from the amplification circuit and the preset threshold before the adjustment. If the number of random noise points is greater than the preset noise point threshold, the noise signal can be determined to be higher than the preset threshold; otherwise, the noise signal can be determined to be lower than the preset threshold.

A second implementation method for the control circuit 140 to determine whether the noise signal is higher than the preset threshold may be as follow. The distance measuring device may include a root mean square detector, and the control circuit 140 may be electrically connected to the amplification circuit 120 through the root mean square detector. The root mean square detector may be configured to detect the power information of the noise signal in a predetermined frequency range, the output the power information to the control circuit 140. The control circuit 140 may also be used to determine whether the power information input by the root mean square detector exceeds a predetermined power threshold. If the power information exceeds the predetermined power threshold, the noise signal can be determined to be higher than the preset threshold; otherwise, the noise signal can be determined to be lower than the preset threshold.

A third implementation method for the control circuit 140 to determine whether the noise signal is higher than the preset threshold may be as follow. The comparison circuit 130 may include a plurality of comparators and a plurality of TDCs, and the plurality of TDCs and the plurality of comparators may be connected in a one-to-one correspondence. The first input terminals of the plurality of comparators may be used to receive electrical signals input from the amplification circuit 120. The second input terminals of the plurality of comparators may be connected to the control circuit 140 and configured to receive the thresholds. The output terminals of the plurality of comparators may be respectively electrically connected to the controller (the control circuit 140 may include one or more controllers) through the TDCs. The comparators may output the comparison results to the TDCs, and the TDCs may measure the time information based on the comparison results and output the electrical signals to the controller. The control circuit 140 may be configured to calculate and compare the first time information corresponding to a first threshold comparator in the plurality of comparators and the second time information corresponding to a second threshold comparator, where the first threshold may be less than the second threshold. In some embodiments, if the difference between the first time information and the second time information is a random value, and the difference between the first time information and the second time information is greater than a predetermined time threshold, the noise signal can be determined to be higher than the first threshold.

In some embodiments, when the distance measuring device includes a plurality of comparators and a plurality of TDCs, the control circuit 140 may be further configured to select the smallest threshold that is higher than the threshold of the noise signal as the preset threshold, and obtain the minimum threshold that is higher than the threshold of the noise signal and the time information of the electrical signal input from the amplification circuit and output through the comparison circuit. Subsequently, on the basis that the preset threshold is greater than the noise signal, the preset threshold may be reduced as much as possible, such that the time information extracted by the comparison circuit 130 may be closer to the real time when the electrical signal input from the amplification circuit 120 passes through the comparison circuit 130, thereby reducing the error caused by the change of the signal amplitude to the collection of the time information, and the accuracy of the time measurement is high.

In some embodiments, when the distance measuring device includes a plurality of comparators and a plurality of TDCs, the thresholds of the plurality of comparators may be the same, and the control circuit 140 may be further configured to calculate the time information corresponding to the electrical signal based on the time information measured by the plurality of TDCs. For example, an average value of the time information measured by the TDCs can be taken as the time information corresponding to the electrical signal, and then the time information corresponding to the electrical signal can be calibrated, such that the accuracy of the time measurement can be improved.

In some embodiments, when the distance measuring device includes a plurality of comparators and a plurality of TDCs, the threshold of the plurality of comparators may be different, and the control circuit 140 may be further configured to fit the waveform of the electrical signal input to the comparator based on the time information measured by the plurality of TDCs, and calculate the time information corresponding to the electrical signal based on the fitted waveform. Referring to FIG. 5, T0 can be considered as the time information corresponding to the electrical signal, such that the accuracy of the time measurement can be improved.

It should be noted that the light pulse signal may be emitted by other devices, or may be emitted by the distance measuring device of the present disclosure. When the light pulse signal is emitted by other devices (such as the laser connected to the distance measuring device), the laser may communicate with the distance measuring device. In this way, the distance measuring device may obtain one or more control parameters such as the emission power of the laser emitter, the wavelength of the transmitted laser, and the emission direction, and obtain information such as the direction of the obstacle based on the control parameters.

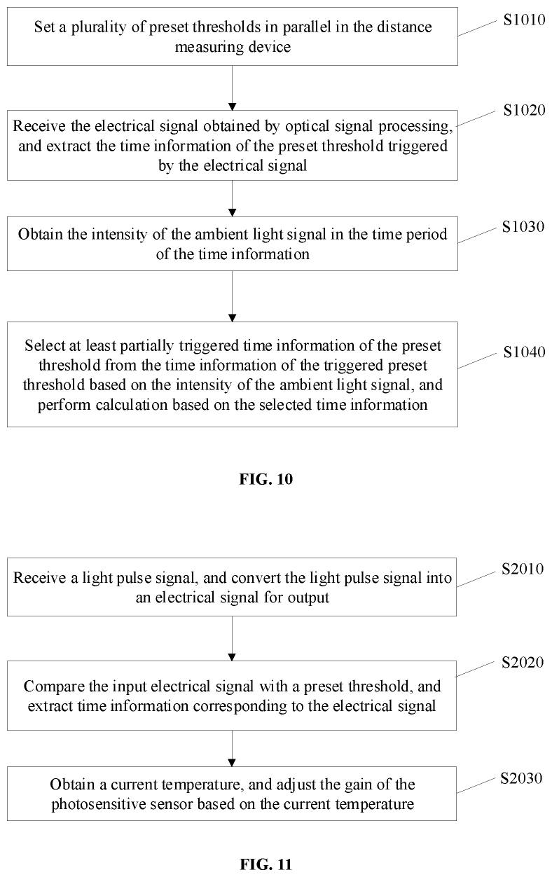

Referring to FIG. 10. Consistent with the above technical solution, FIG. 10 is a flowchart of a time measurement method based on the distance measuring device according to an embodiment of the present disclosure. It should be noted that although the signal processing method disclosed in this method embodiment can be implemented based on the distance measuring device shown in FIG. 1, FIG. 2, or FIG. 8, the above example distance measuring device does not constitute a limitation on the signal processing method disclosed in the embodiments of the present disclosure. The signal processing method will be described in detail below.

S1010, setting a plurality of preset thresholds in parallel in the distance measuring device.

S1020, receiving the electrical signal obtained by optical signal processing, and extracting the time information of the preset threshold triggered by the electrical signal.

S1030, obtaining the intensity of the ambient light signal in the time period of the time information.

S1040, selecting at least partially triggered time information of the preset threshold from the time information of the triggered preset threshold based on the intensity of the ambient light signal, and performing calculation based on the selected time information.

In the process at S1040, the calculation may at least include determining the distance between the object and the distance measuring device based on the time information output by the comparison circuit.

It can be understood that after the process at S1040, the distance measuring device may further include other processes, which are not limited in the present disclosure.

In the process at S1010, three or more preset thresholds may be set in parallel, such that in the subsequent process, after receiving the electrical signal obtained through optical signal processing, the comparison circuit may compare the electrical signal with at least a part of the plurality of preset thresholds, and extract the time information of the preset threshold triggered by the electrical signal.

In the process at S1030, the intensity of the ambient light signal may be used as a basis for determining whether the extracted time information is the time information corresponding to the effective light pulse signal to select the preset threshold used for calculation.

In the process at S1020, the method may include comparing the maximum preset threshold triggered by the electrical signal with the maximum preset threshold corresponding to the intensity of the ambient light signal; determining that the light signal is a noise signal if the maximum preset threshold triggered by the electrical signal is not greater than the maximum preset threshold corresponding to the intensity of the ambient light signal; and/or, determining that the light signal includes a valid light pulse signal if the maximum preset threshold triggered by the electrical signal is greater than the maximum preset threshold corresponding to the intensity of the ambient light signal.

In some embodiments, if the maximum preset threshold triggered by the electrical signal is greater than the maximum preset threshold corresponding to the intensity of the ambient light signal, the arithmetic circuit may be used to select at least the time information when the preset threshold that is greater than the maximum preset threshold corresponding to the intensity of the ambient light signal is triggered.

In some embodiments, if the maximum preset threshold triggered by the electrical signal is greater than the maximum preset threshold corresponding to the intensity of the ambient light signal, the arithmetic circuit may be used to discard the preset threshold when the preset threshold is smaller than the maximum preset threshold corresponding to the intensity of the ambient light signal.

In one embodiment of the present disclosure, determining the preset threshold to be selected for comparison may be based on the intensity of the ambient light signal. For example, when it is detected that the external ambient light is relatively weak, all preset thresholds may be selected for comparison, and then the time information of the preset threshold triggered by the electrical signal can be extracted. When it is detected that the external ambient light is relatively strong, some preset thresholds with smaller values may be turned off, and no comparison may be performed or the subsequent calculation may not be performed. When the external light is relatively strong, the threshold at the bottom may trigger a certain amount of noise, but these data are not calculated as signals, and the final point cloud output by the radar will not include noise.

Further, if the maximum preset threshold triggered by the electrical signal is greater than the maximum preset threshold corresponding to the intensity of the ambient light signal, the arithmetic circuit may be used to select at least the time information when the preset threshold that is greater than the maximum preset threshold corresponding to the intensity of the ambient light signal is triggered.

As an example, if the maximum preset threshold triggered by the electrical signal is greater than the maximum preset threshold corresponding to the intensity of the ambient light signal, all preset thresholds may be compared with the electrical signal to extract the corresponding time information. In all the extracted time information, the time information generated by the preset threshold that is greater than the maximum preset threshold corresponding to the intensity of the ambient light signal may be the time information generated by the valid electrical pulse signal, and the time information generated by the preset threshold that is smaller than the maximum preset threshold corresponding to the intensity of the ambient light signal may be the overlap of the time information generated by the valid electrical pulse signal and the time information generated by the environmental noise.

As an example, when the maximum preset threshold triggered by the electrical signal is greater than the maximum preset threshold corresponding to the intensity of the ambient light signal, in order to improve the efficiency of time information extraction, the comparison circuit can be used to discard a preset threshold less than the maximum preset threshold corresponding to the intensity of the ambient light signal without comparing it with the electrical signal. That is, the overlapping data of the time information generated by the valid electrical pulse signal and the time information generated by the environmental noise can be discarded, and the time information may not be output.

In some embodiments, another method for determining the time information as a valid electrical pulse signal or noise may include the following. The arithmetic circuit may be configured to compare the number of time information extracted by the comparison circuit and the number of thresholds that can be trigged by the intensity of the ambient light signal. If the number of time information extracted by the comparison circuit is not greater than the number of time information generated by the ambient light signal, the optical signal can be determined as a noise signal; and/or, if the number of time information extracted by the comparison circuit is greater than the number of time information generated by the ambient light signal, the optical signal may include a valid light pulse signal.

A program may be used to dynamically select the effective thresholds to be used in the calculation, and realize the technical solution of dynamically adjusting the thresholds. The fineness of the adjustable threshold in the above manner depends on the number thresholds. When the number of thresholds is relatively large, the number of processes that can be achieved may be greater, which can further improve the time information extraction efficiency.

In the embodiments of the present disclosure, in the process at S1030, the distance measuring device may be configured to obtain and compare the intensity of the optical noise signal and the intensity of the electrical noise signal. When the intensity of the optical noise signal is less than the intensity of the electrical noise signal, the distance measuring device may adjust the preset threshold for comparison such that the noise signal can be lower than the preset threshold. When the intensity of the optical noise signal is greater than the intensity of the electrical noise signal, the distance measuring device may adjust the gain of the photosensitive sensor such that the noise signal can be lower than the preset threshold.

In the embodiments of the present disclosure, in the process at S1030, the distance measuring device may be configured to obtain the intensity of the noise signal in the amplified electrical signal. When the intensity of the n is less than the preset noise threshold, the distance measuring device may adjust the preset threshold for comparison such that the noise signal can be lower than the preset threshold. When the intensity of the noise signal is greater than the preset noise threshold, the distance measuring device may adjust the gain of the photosensitive sensor such that the noise signal can be lower than the preset threshold.

In the embodiments of the present disclosure, after the process at S1020 and before the process at S1030, the distance measuring device may be further configured to determine whether the noise signal is higher than the preset threshold. When the noise signal is higher than the preset threshold, the distance measuring device may perform the process at S1010; otherwise, the distance measuring device may not adjust the gain of the photosensitive sensor or the preset threshold of the comparison circuit, and perform the process at S1040.

A first implementation method for the distance measuring device to determine whether the noise signal is higher than the preset threshold may as follow. The distance measuring device may be configured to obtain the number of random noise points in the initial image generated by the distance measuring device, and determine whether the number of random noise points is greater than the preset noise point threshold. The initial image may be generated by the distance measuring device based on the amplified electrical signal and the preset threshold before the adjustment. If the number of random noise points is greater than the preset noise point threshold, the noise signal can be determined to be higher than the preset threshold, and the distance measuring device may perform the process at S1030; otherwise, the distance measuring device may not adjust the gain of the photosensitive sensor or the preset threshold of the comparison circuit, and perform the process at S1040.

A second implementation method for the distance measuring device to determine whether the noise signal is higher than the preset threshold may be as follow. The distance measuring device may detect the power information of the noise signal in the predetermined frequency range. If the power information exceeds the predetermined power threshold, the noise signal can be determined to be higher than the preset threshold, and the distance measuring device may perform the process at S1030; otherwise, the distance measuring device may not adjust the gain of the photosensitive sensor or the preset threshold of the comparison circuit, and perform the process at S1040.

A third implementation method for the distance measuring device to determine whether the noise signal is higher than the preset threshold may be as follow. The distance measuring device may include a plurality of comparators and a plurality of TDCs, and the plurality of TDCs and the plurality of comparators may be connected in a one-to-one correspondence. The distance measuring device may compare the amplified electrical signal with the thresholds of the plurality of comparators, extract the time information measured by the plurality of TDCs, and calculate and compare the first time information corresponding to the first threshold comparator in the plurality of comparators and the second time information corresponding to the second threshold comparator. In some embodiments, the first threshold may be less than the second threshold. If the difference between the first time information and the second time information is a random value, and the difference between the first time information and the second time information is greater than the predetermined time threshold, the noise signal can be determined to be higher than the first threshold. At this time, the distance measuring device may perform the process at S1030; otherwise, the distance measuring device may not adjust the gain of the photosensitive sensor or the preset threshold of the comparison circuit, and perform the process at S1040.

In some embodiments, after determining whether the noise signal is higher than the preset threshold, and before adjusting the preset threshold for comparison, the method may further include selecting the smallest threshold that is higher than the noise signal as the preset threshold, and obtain the minimum threshold that is higher than the threshold of the noise signal and the time information output by the comparison circuit of the amplified electrical signal. Subsequently, on the basis that the preset threshold is greater than the noise signal, the preset threshold may be reduced as much as possible, such that the time information extracted by the comparison circuit may be closer to the real time obtained by the electrical signal after the amplification operation, thereby reducing the error caused by the change of the signal amplitude to the collection of the time information, and the accuracy of the time measurement is high.

In some embodiments, when the distance measuring device includes a plurality of comparators and a plurality of TDCs, and the plurality of TDCs and the plurality of comparators may be connected in a one-to-one correspondence, the thresholds of the plurality of comparators may be the same. In this case, in the process at S1040, the distance measuring device may compare the amplified electrical signal with the thresholds of the plurality of comparators, extract the time information measured by the plurality of TDCs (e.g., t1, t2, t3, t4, t5), and calculate the time information corresponding to the electrical signal based on the time information measured by the plurality of TDCs. The calculation method may include taking the average of t1, t2, t3, t4, and t5 as the time information corresponding to the electrical signal.

In some embodiments, when the distance measuring device includes a plurality of comparators and a plurality of TDCs, and the plurality of TDCs and the plurality of comparators may be connected in a one-to-one correspondence, the thresholds of the plurality of comparators may be the different. In this case, in the process at S1040, the distance measuring device may compare the amplified time information with the thresholds of the plurality of comparators, and measure the time information corresponding to the plurality of comparators through the plurality of TDCs, such as (v1, t1), (v2, t2), (v3, t3), (v4, t4), and (v5, t5). Then the waveform of the amplified electrical signal may be fitted based on the time information measured by the plurality of TDCs, and the time information corresponding to the electrical signal may be calculated based on the fitted waveform. Referring to FIG. 5, T0 can be considered as the time information corresponding to the electrical signal.

As mentioned above, an amplification circuit may be arranged before the comparison circuit, and the amplification circuit may amplify the electrical signal before inputting it into the comparison circuit. In practical applications, the amplification circuit may include many structures.

In some electronic devices, such as a lidar, generally involves the processes of signal acquisition and amplification of the acquired signals. However, the energy of the signals acquired by the lidar generally has a wide range. That is, when the obstacle is close to the lidar, the energy of the signal obtained by the lidar through the receiving tube may be relatively high, and when the obstacle is far away from the lidar, the energy of the signal obtained through the receiving tube may be relatively low. When the electrical signal input by the amplification circuit is too large, the operation of the amplification circuit may be saturated. Saturation will cause distortion of the output signal, which will affect the distance measurement of the lidar. In addition, it takes a certain amount of time for the lidar to return to normal after saturation, which makes the lidar unable to respond continuously, resulting in a measurement blind zone. The embodiments of the present disclosure further provide some amplification circuits, which can improve the conventional amplification circuit.

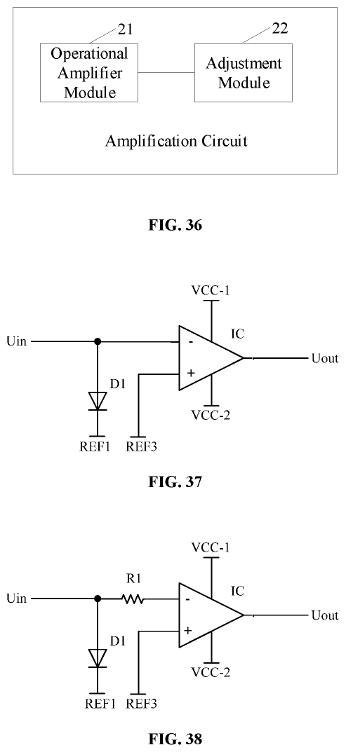

FIG. 36 is a schematic diagram of an amplification circuit according to an embodiment of the present disclosure. As shown in FIG. 36, the amplification circuit includes an operational amplifier module 21 and an adjustment module 22. The adjustment module 22 may be positioned at one or more of the front stage circuit, the rear stage circuit, or the feedback circuit of the operational amplifier module 21. The adjustment module 22 can be used to adjust the amplification factor of the input signal of the amplification circuit, such that the amplification circuit can amplify the energy of the input signal with the adjusted amplification factor and output it.

It can be understood that the amplification factor of the amplification circuit may be equal to the ratio of the output signal of the amplification circuit to the input signal of the amplification circuit.

It can be understood that the adjustment module 22 can adjust the amplification factor. In this way, when the energy of the input signal of the amplification circuit is greater than the threshold, the greater the energy of the input signal, the smaller the amplification factor of the input signal by the amplification circuit.

In some embodiments, the adjustment module 22 may include a first clamping module. The first clamping module may be positioned on the front circuit of the operational amplifier module 21. The first clamping module may be connected to the first input terminal of the operational amplifier module 21, and the second input terminal of the operational amplifier module 21 may be connected to a third reference level REF3. The first clamping module may be used to adjust the input signal of the operational amplifier module 21 and output the signal through the output terminal of the operational amplifier module 21.

In some embodiments, when the input signal of the amplification circuit is a voltage signal, the first clamping module may include a first diode. Referring to FIG. 37, which is a first wiring diagram of the amplification circuit according to an embodiment of the present disclosure. FIG. 37 uses the operational amplifier module 21 as an operational amplifier IC as an example to illustrate the connection relationship of the amplification circuit. As shown in FIG. 37, when the voltage signal is a positive voltage signal, the anode of the first diode D1 is connected to the first input terminal of the operational amplifier module 21 (that is, the inverted input terminal of the operational amplifier IC). The cathode of the first diode D1 is connected to a first reference level REF1. The input signal Uin of the amplification circuit is input through the common terminal of the anode of the first diode D1 and the inverted input terminal of the operational amplifier IC, and the output terminal of the operational amplifier IC is the output terminal Uout of the amplification circuit. The second input terminal of the operational amplifier module 21 (that is, the same direction input terminal of the operational amplifier IC) is connected to the third reference level REF3.

When the voltage signal input to the amplification circuit exceeds the conduction voltage drop of the first diode D1, the first diode D1 can be turned on, such that the voltage signal input to the operational amplifier module 21 can be limited to near the conduction voltage of the first diode, thereby preventing the input saturation of the operational amplifier module 21.

It can be understood that when the input signal of the amplification circuit is a negative voltage signal, the connection of the anode and the cathode of the first diode may be opposite to the connection of the anode and the cathode of the first diode D1 in the amplification circuit shown in FIG. 37.

In some embodiments, when the input signal of the amplification circuit is a current signal, the first clamping module may include a first diode and a first resistor. Referring to FIG. 38, which is a second wiring diagram of the amplification circuit according to an embodiment of the present disclosure. FIG. 38 uses the operational amplifier module 21 as an operational amplifier IC as an example to illustrate the connection relationship of the amplification circuit. As shown in FIG. 38, when the voltage signal is a positive current signal, the anode of the first diode D1 is connected to the first input terminal of the operational amplifier module 21 (that is, the inverted input terminal of the operational amplifier IC) through the first resistor R1. The cathode of the first diode D1 is connected to the first reference level REF1, the input signal Uin of the amplification circuit is input through the common terminal of the anode of the first diode D1 and the first resistor, and the output terminal of the operational amplifier IC is the output terminal Uout of the amplification circuit. The second input terminal of the operational amplifier module 21 (that is, the same direction input terminal of the operational amplifier IC) is connected to the third reference level REF3).

When the current signal input to the amplification circuit increases, the voltage drop generated on the first resistor R1 increases. When the voltage drop generated on the first resistor R1 exceeds the conduction voltage drop of the first diode D1, the first diode D1 can be turned on, thereby reducing the current signal input to the operational amplifier module 21 and avoiding the input saturation of the operational amplifier module 21.

It can be understood that when the input signal of the amplification circuit is a negative current signal, the connection of the anode and the cathode of the first diode may be opposite to the connection of the anode and the cathode of the first diode D1 in the amplification circuit shown in FIG. 38.

In some embodiments, the adjustment module 22 may include a second clamping module. The second clamping module may be positioned on the rear circuit of the operational amplifier module 21. The second clamping module may be connected to the output terminal of the operational amplifier module 21, and the second clamping module may be configured to adjust the output signal of the operational amplifier module 21. It can be understood that the input signal of the amplification circuit may be input to the first input terminal of the operational amplifier module, and the input signal of the amplification circuit may also be input to the first input terminal of the operational amplifier module 21 through the first clamping module. Further, the second input terminal of the operational amplifier module is connected to the third reference level REF3.

In some embodiments, when the input signal of the amplification circuit is a voltage signal, the second clamping module may include a second diode. Referring to FIG. 39, which is a third wiring diagram of the amplification circuit according to an embodiment of the present disclosure. FIG. 39 uses the operational amplifier module 21 as an operational amplifier IC as an example to illustrate the connection relationship of the amplification circuit. As shown in FIG. 39, when the voltage signal is a positive voltage signal, the anode of the second diode D2 is connected to the output terminal of the operational amplifier module 21 (that is, the output terminal of the operational amplifier IC). The cathode of the second diode D2 is connected to a second reference level REF2. The output terminal Uout of the amplification circuit is output from the common terminal of the second diode D2 and the output terminal of the operational amplifier IC.

When the voltage signal output from the amplification circuit exceeds the conduction voltage drop of the second diode D2, the second diode D2 can be turned on, thereby limiting the voltage signal input to the rear stage to near the conduction voltage of the second diode D2 and avoiding the saturation of the subsequent operational amplifier.

It can be understood that when the input signal of the amplification circuit is a negative voltage signal, the connection of the anode and the cathode of the second diode may be opposite to the connection of the anode and the cathode of the second diode D2 in the amplification circuit shown in FIG. 39.

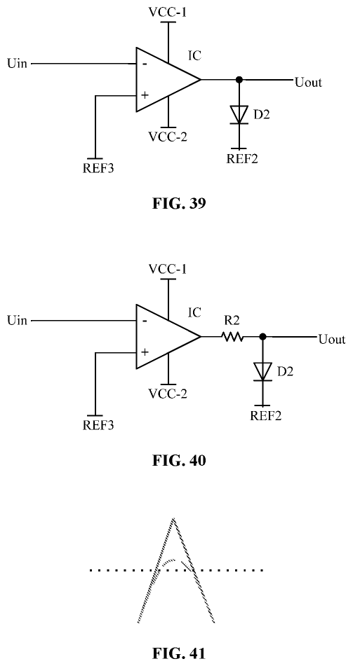

In some embodiments, when the input signal of the amplification circuit is a current signal, the second clamping module may include a second diode and a second resistor. Referring to FIG. 40, which is a fourth wiring diagram of the amplification circuit according to an embodiment of the present disclosure. FIG. 40 uses the operational amplifier module 21 as an operational amplifier IC as an example to illustrate the connection relationship of the amplification circuit. As shown in FIG. 40, when the voltage signal is a positive current signal, the anode of the second diode D2 is connected to the output terminal of the operational amplifier module 21 (that is, the output terminal of the operational amplifier IC) through the second resistor R2. The cathode of the second diode D2 is connected to the second reference level REF2, and the output terminal Uout of the amplification circuit is output from the common terminal of the second diode D2 and the second resistor R2.

When the current signal output from the operational amplifier module 21 increases, the voltage drop generated on the second resistor R2 increases. When the voltage drop generated on the second resistor R2 exceeds the conduction voltage drop of the second diode D2, the second diode D2 can be turned on, thereby reducing the current signal to be output and avoiding the saturation of the operational amplifier.

It can be understood that when the input signal of the amplification circuit is a negative current signal, the connection of the anode and the cathode of the second diode may be opposite to the connection of the anode and the cathode of the second diode D2 in the amplification circuit shown in FIG. 40.

It can be understood that in the wiring diagram of the amplification circuit shown in FIG. 39 or FIG. 40, the input signal Uin of the amplification circuit can be directly input to the first input terminal of the operational amplifier module 21 (that is, the inverted input terminal of the operational amplifier IC), and the same direction input terminal of the operational amplifier IC can be connected to the third reference level REF3.

Referring to FIG. 41, which is an effect diagram of the first clamping module before and after clamping according to an embodiment of the present disclosure. In FIG. 41, the solid line is the actual signal, the dotted line represents the conduction voltage of the first diode D1, and the dotted curve represents the signal after clamping. Similarly, the effects before and after the clamping of the second clamping module are also shown in FIG. 41.

In some embodiments, the adjustment module 22 may include a third clamping module. The third clamping module may be positioned on the feedback circuit of the operational amplifier module 21. The first input terminal of the operational amplifier module 21 may be connected to the first terminal of the third clamping module, and the output terminal of the operational amplifier module 21 may be connected to the second terminal of the third clamping module. The third clamping module may be configured to reduce the amplification factor of the operational amplifier module 21 to the input signal of the operational amplifier module 21 when the energy information of the signal input to the operational amplifier module 21 is greater than the first threshold.

It can be understood that the input signal of the amplification circuit may be input to the first input terminal of the operational amplifier module 21, or the input signal of the amplification circuit may also be connected to the first input terminal of the operational amplifier module 21 through the first clamping module. Further, the second input terminal of the operational amplifier module 21 may be connected to the third reference level REF3.

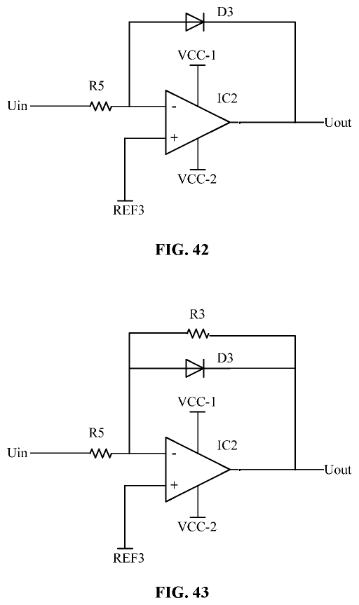

In some embodiments, the third clamping module may include a third diode and a fifth resistor. Referring to FIG. 42, which is a fifth wiring diagram of the amplification circuit according to an embodiment of the present disclosure. FIG. 42 uses the operational amplifier module 21 as an operational amplifier IC as an example to illustrate the connection relationship of the amplification circuit. As shown in FIG. 42, the anode of the third diode D3 is connected to the first input terminal of the operational amplifier module 21 (that is, the inverted input terminal of the operational amplifier IC), and the cathode of the third diode D3 is connected to the output terminal of the operational amplifier module 21 (that is, the output terminal of the operational amplifier IC). The second input terminal of the operational amplifier module 21 (that is, the same direction input terminal of the operational amplifier IC) is connected to the third reference level REF3. The input signal Uin of the amplification circuit is input through to the inverted input terminal of the operational amplifier IC through the fifth resistor R5. The inverted input terminal of the operational amplifier IC is the output terminal Uout of the amplification circuit.

When the energy of the signal input to the operational amplifier module 21 is relatively small, the voltage across the third diode D3 may be relatively small, the third diode D3 may not be conducting, and the resistance RD3 of the third diode D3 may be relatively large. At this time, the amplification factor of the operational amplifier module 21 may be RD3/R5, and the operational amplifier module 21 may amplify the signal input to the operational amplifier module 21. When the energy of the signal input to the operational amplifier module 21 is relatively large, the voltage across the third diode D3 may be greater than the conduction voltage of the third diode D3, the third diode D3 may be turned on, and the resistance RD3 of the third diode D3 may be relatively small. At this time, the amplification factor RD3/R5 of the operational amplifier module 21 may be reduced, which can reduce the energy of the signal output from the operational amplifier module 21, thereby reducing the amplification factor of the amplification circuit.

In some embodiments, the third clamping module may include a third diode, a third resistor, and a fifth resistor. Referring to FIG. 43, which is a sixth wiring diagram of the amplification circuit according to an embodiment of the present disclosure. FIG. 43 uses the operational amplifier module 21 as an operational amplifier IC as an example to illustrate the connection relationship of the amplification circuit. As shown in FIG. 43, the anode of the third diode D3 is connected to the first input terminal of the operational amplifier module 21 (that is, the inverted input terminal of the operational amplifier IC), the cathode of the third diode D3 is connected to the output terminal of the operational amplifier module 21 (that is, the output terminal of the operational amplifier IC), and the third resistor R3 is connected in parallel with the third diode D3. The second input terminal of the operational amplifier module 21 (that is, the same direction input terminal of the operational amplifier IC) is connected to the third reference level REF3. The input signal Uin of the amplification circuit is input through to the inverted input terminal of the operational amplifier IC through the fifth resistor R5. The inverted input terminal of the operational amplifier IC is the output terminal Uout of the amplification circuit.

When the energy of the signal input to the operational amplifier module 21 is relatively small, the voltage across the third diode D3 may be relatively small, the third diode D3 may not be conducting, the resistance RD3 of the third diode D3 may be relatively large, and the equivalent resistance R_{equivalent} of the third diode D3 and the third resistor R3 in parallel may be relatively large. At this time, the amplification factor of the operational amplifier module 21 may be R_{equivalent}/R5, and the operational amplifier module 21 may amplify the signal input to the operational amplifier module 21. When the energy of the signal input to the operational amplifier module 21 is relatively large, the voltage across the third diode D3 may be greater than the conduction voltage of the third diode D3, the third diode D3 may be turned on, the resistance RD3 of the third diode D3 may be relatively small, and the R_{equivalent} may be relatively small. At this time, the amplification factor R_{equivalent}/R5 of the operational amplifier module 21 may be reduced, which can reduce the energy of the signal output from the operational amplifier module 21, thereby reducing the amplification factor of the amplification circuit.

In some embodiments, the third clamping module may include a third diode, a third resistor, a fourth resistor, and a fifth resistor. Referring to FIG. 44, which is a seventh wiring diagram of the amplification circuit according to an embodiment of the present disclosure. FIG. 44 uses the operational amplifier module 21 as an operational amplifier IC as an example to illustrate the connection relationship of the amplification circuit. As shown in FIG. 44, the anode of the third diode D3 is connected to the first input terminal of the operational amplifier module 21 through the third resistor R3, the cathode of the third diode D3 is connected to the output terminal of the operational amplifier module 21, and the fourth resistor R4 is connected in parallel with the third diode D3. The second input terminal of the operational amplifier module 21 (that is, the same direction input terminal of the operational amplifier IC) is connected to the third reference level REF3. The input signal Uin of the amplification circuit is input through to the inverted input terminal of the operational amplifier IC through the fifth resistor R5. The inverted input terminal of the operational amplifier IC is the output terminal Uout of the amplification circuit.

When the energy of the signal input to the operational amplifier module 21 is relatively small, the voltage across the third diode D3 may be relatively small, the third diode D3 may not be conducting, the resistance RD3 of the third diode D3 may be relatively large, and the equivalent resistance R_{equivalent} of the third diode D3 and the fourth resistor R3 connected in parallel that is connected in series with the third resistor R3 may be relatively large. At this time, the amplification factor of the operational amplifier module 21 may be R_{equivalent}/R5, and the operational amplifier module 21 may amplify the signal input to the operational amplifier module 21. When the energy of the signal input to the operational amplifier module 21 is relatively large, the voltage across the third diode D3 may be greater than the conduction voltage of the third diode D3, the third diode D3 may be turned on, the resistance RD3 of the third diode D3 may be relatively small, and the R_{equivalent} may be relatively small. At this time, the amplification factor R_{equivalent}/R5 of the operational amplifier module 21 may be reduced, which can reduce the energy of the signal output from the operational amplifier module 21, thereby reducing the amplification factor of the amplification circuit.

It should be noted that in the embodiments shown in FIG. 42, FIG. 43, and FIG. 44, the fifth resistor R5 may not be a needed component of the third clamping module. For an operational amplifier IC with a stable operational amplifier, the input signal Uin of the amplification circuit may also be directly input to the inverted input terminal of the operational amplifier IC.

It can be understood that that in the embodiments shown in FIG. 42, FIG. 43, and FIG. 44, the input signal of the amplification circuit may be a positive current signal or a positive voltage signal. When the input signal of the amplification circuit is a negative voltage signal or a negative current signal, the connection of the anode and cathode of the third diode may be opposite to the connection of the anode and cathode of the third diode D3 in the amplification circuit shown in FIG. 42, FIG. 43, and FIG. 44.

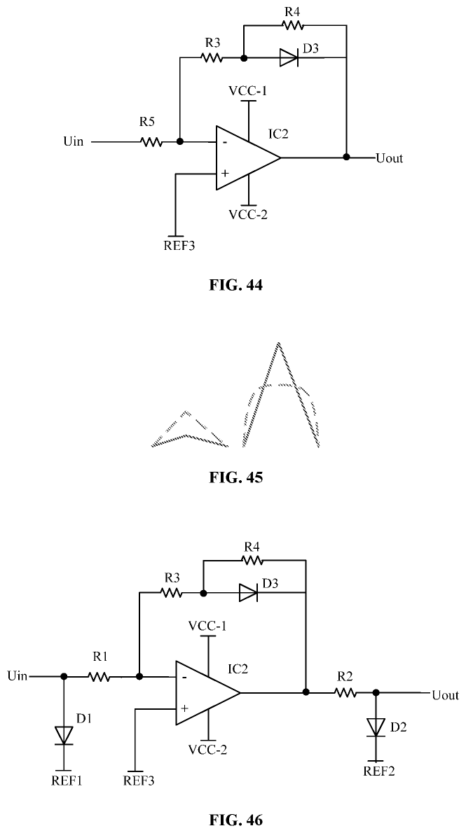

Referring to FIG. 45, which is an effect diagram of a third clamping module before and after clamping according to an embodiment of the present disclosure. The solid line in FIG. 45 is the actual signal, and the dotted line is the signal after clamping. When the energy of the signal is relatively small, as shown in the curve on the left of FIG. 45, the third clamping module can amplify the input signal. When the energy of the signal is relatively large, as shown in the curve on the right of FIG. 45, the amplification factor of the operational amplifier module 21 can be reduced such that its output signal does not exceed the conduction voltage of the third diode D3.

In some embodiments, the amplification circuit may include a first clamping module, a second clamping module, and a third clamping module at the same time. Referring to FIG. 46, which is an eighth wiring diagram of the amplification circuit according to an embodiment of the present disclosure. For a detailed description, reference may be made to the relevant descriptions of the first clamping module, the second clamping module, and the third clamping module, which will not be repeated here.

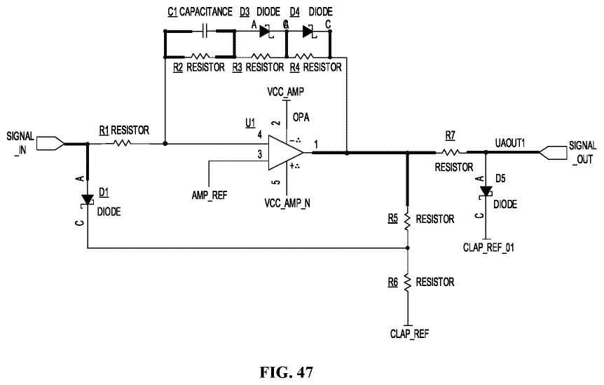

Referring to FIG. 47, which is a wiring diagram of the clamping circuit of the amplification circuit according to an embodiment of the present disclosure. FIG. 47 includes an operational amplifier module and a clamping circuit. The clamping circuit may be configured to clamp the input signal of the amplification circuit, such that after the input signal of the amplification circuit is clamped, its magnitude may fluctuate within a certain range to prevent the saturation output of the operational amplifier module.

As shown in FIG. 47, the anode of the first diode D1 is connected to the signal input terminal Signal In, the cathode of the first diode D1 is connected to the output terminal of the operational amplifier through a resistor R5, and the cathode of the first diode D1 is also connected to a reference voltage CLAP REF through a resistor R6. That is, R5 and R6 constitute a voltage divider resistor, which can adjust the trigger position of a specific threshold. Of course, in other embodiments, the cathode of the first diode D1 may be directly connected to the output of the operational amplifier. R2, R3, and R4 may be connected in series to form a feedback circuit. Both ends of R2 are connected in parallel with a capacitor C1, and both ends of R3 and R4 are connected in parallel with diodes D3 and D4. The feedback circuit described above can adopt a graded conduction circuit. Of course, in other embodiments, the number of resistors in the feedback circuit may be two or more, and each resistor may be connected to a parallel capacitor or a diode. Such setting can reduce the parasitic parameters on the resistor in the feedback circuit, such that the parasitic capacitance on the feedback resistor can be reduced, thereby achieving a high bandwidth. By connecting a capacitor in series with the feedback resistor, the capacitor can compensate the feedback resistor to ensure the stability of the feedback system. Of course, in other embodiments, the feedback circuit may not be included. The anode of a fifth diode D5 is connected to the output terminal of the operational amplifier module through a seventh resistor R7, and the cathode of the fifth diode D5 is connected to a reference voltage CALP_REF_01. Of course, in other embodiments, the fifth diode D5 and the seventh resistor R7 may not be included.

When the energy of the signal input to the operational amplifier module is relatively small, the voltage across the first diode D1 may be relatively low, and the operational amplifier module may amplify the signal input to the operational amplifier module. Since the input signal enters the inverted input terminal, the output signal may be relatively large. At this time, the voltage divided to the cathode of the first diode may also be relatively high, and the voltage across the first diode may become higher. In this way, the input signal can obtain a higher range without causing the first diode to conduct. When the energy of the signal input to the operational amplifier module is relatively large, the voltage across the first diode D1 may be relatively high, such that the first diode may be turned on, and the current may flow to CALP_REF through the first diode, but may not flow to the operational amplifier to be amplified. The operational amplifier module may amplify the signal input to the operational amplifier module. Since the input signal enters the inverted input terminal, the output signal may be relatively small. At this time, the voltage divided to the cathode of the first diode may also be relatively low, the conduction voltage difference of the first diode may become smaller, and the input signal may increase slightly, which can cause the first diode to conduct. Therefore, the high value of the input voltage can be limited to a smaller range.

Based on the circuit structure shown in FIG. 47, the reference voltage of the first diode D1 can fluctuate with the signal. When the signal is relatively strong, a low level may be output. At this time, the reference voltage of the first diode D1 may swing downward, such that the first diode D1 can be turned on when the signal is slightly larger, which has a stronger clamping effect.

Of course, the inverted amplifier in FIG. 47 may also be a forward amplifier, and the corresponding strong clamp can also be obtained by adjusting the circuit.

It should be noted that the first diode D1, the second diode D2, the third diode D3, the fourth diode D4, and the fifth diode D5 may also be Zener diodes or TVS diodes. At this time, the conduction voltage of the diode may be the breakdown voltage of the Zener diode or the TVS diode.

It should also be noted that, in the embodiments of the present disclosure, the first reference level, the second reference level, and the third reference level are being used to distinguish the reference levels, where the first reference level, the second reference level, or the third reference level may be the same or different.

Compared with the conventional technology, the amplification circuit provided by the present disclosure includes an operational amplifier circuit and a clamping circuit. The clamping circuit can be used to clamp the input signal of the amplification circuit, such that the input signal of the amplification circuit can be clamped, its magnitude can fluctuate within a certain range to prevent the saturation output of the operational amplifier circuit. By using the amplification circuit, the reference voltage of the clamping circuit of the amplification circuit can be dynamically adjusted based on the energy of the input signal, which has a stronger clamping function and avoids saturation of the operational amplifier.

In some application fields (such as lidar, laser distance measurement, etc.), since the product is directly used in the real life scenarios, there is a risk that the laser will directly enter the human eye. Therefore, the +Accessible Emission Limit (AEL) mandates that the laser emission cannot exceed the radiation value of the safety regulations. At the same time, when a single failure occurs in the system, the laser emission power cannot exceed the value specified by the safety regulations. Therefore, an embodiment of the present disclosure further provides a laser emission solution that complies with human eye safety regulations. When a single failure occurs in the system, the protection circuit can ensure that the laser radiation value does not exceed the safety value.

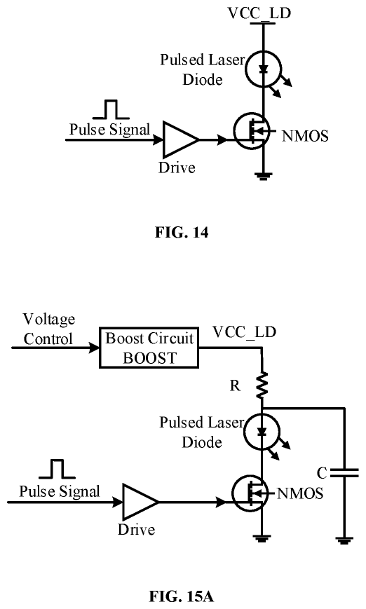

Referring to FIG. 14, a conventional pulse-driven light emitting device includes a power supply, a light source, and a control circuit. The power supply is VCC_LD, the light source is a pulsed laser diode, and the control circuit includes a driving circuit and a switching circuit NMOS. When the pulse signal is high, the drive can output high voltage and high current, and quickly turn on the MOS tube. The cathode of the pulsed laser diode is grounded, and the anode is connected to the power supply VCC_LD. There may be a voltage difference, and the laser diode can be turned on and emit light. When the pulse signal is low, the MOS tube can be cut off, such that the laser diode can also be cut off. Therefore, by controlling the duty cycle and frequency of the pulse signal, the duration and frequency of the laser diode's light emission can be controlled, thereby controlling the radiation amount of the laser diode.

In the conventional technology, if there is a single failure in the system, for example, (1) there is a bug in the software, and the pulse width of the pulse signal is too large; (2) the MOS tube fails and is directly short-circuited; and (3) the power supply is faulty, and VCC_LD is too high. When there is a bug in the software, excessive pulse width may cause the laser diode to emit light for an extended period of time, which can cause the total radiation to exceed a predetermined value, which can exceed the specified value for human eye safety. When the MOS tube fails, the laser diode may be constantly in the light-emitting state, which can cause the total radiation to exceed a predetermined value, which can exceed the specified value for human eye safety. When the power supply is faulty, to voltage of the power supply may be too high, which can cause excessive laser power, exceeding the specified value for human eye safety. It can be seen that as long as any one of the foregoing three conditions occur, the luminous radiation or luminous power of the laser diode will exceed the specified value for human eye safety, and causing damage to the human eye.

In some embodiments, the light emitting circuit may be as shown in FIG. 15A. The light emitting circuit includes a power supply, a light source, a control circuit, and an energy storage circuit. The power supply is VCC_LD, as the energy supply of the light source. The light source is a pulsed laser diode. The control circuit includes a driving circuit and a switching circuit NMOS. The energy storage circuit includes a resistor R and a capacitor C. In some embodiments, the energy storage circuit may be a capacitor C, and the charging circuit may be the resistor R.

A voltage control signal may be used to set the output value of the boost circuit BOOST to adjust the working voltage of the laser diode VCC_LD. When the pulse signal is low, the MOS tube can be cut off, such that the laser diode can also be cut off. At this time, the capacitor C can be charged through the resistor R until the capacitor voltage is VCC_LD.

When the pulse signal is high, the drive can output high voltage and high current, and quickly turn on the MOS tube. The capacitor C can be discharged through the laser diode and the MOS tube, such that the laser diode can be turned on and emit light. That is, the control circuit can be used to turn on VCC_LD and the capacitor C in a first period of time, such that the power supply can charge the capacitor C until the capacitor voltage is saturated. The control circuit can also be used to turn on the laser diode and the capacitor C in a second period of time. As such, the capacitor C can supply power to the laser diode, such that the light source can emit a light pulse signal until the output current of the capacitor is lower than threshold current of the laser transmitter. The energy stored in the energy storage circuit may have an upper limit, which can be determined by the capacitance value of the capacitor C and the working voltage VCC_LD.

In some embodiments, the emission power of the laser diode may be related to the amount of charge in the capacitor. When the output current of the capacitor is lower than the threshold current of the laser diode, the laser diode may stop emitting light. Since the light-emitting power and light-emitting time of the laser diode may only be related to the capacitor C, even if there is a bug in the software and the pulse width of the pulse signal is too large, at this time, the MOS tube has been turned on for a long time, but luminous power of the laser diode may be mainly related to the amount of charge of the capacitor, and may not be related to the pulse signal. Therefore, after one light emission, the amount of capacitor charge may not be enough to excite the diode to emit light, even if the MOS tube is turned on, it will not continue to emit light. When the MOS tube fails and is directly short-circuited, similar to having a bug in the software, after the laser diode emits light once, it will not continue to emit light.

In some embodiments, as shown in FIG. 15B, the light emitting circuit further includes a Zener diode connected in parallel with the capacitor C to protect the voltage of the capacitor C from exceeding a predetermined value. Even if the emission voltage is too high, the Zener diode can be turned on and shunted. As such, when the power supply is faulty, the power of the laser diode may not exceed the predetermined value. Therefore, this embodiment can improve the situation of the diode output exceeding the safety value caused by the three types of failures described above.

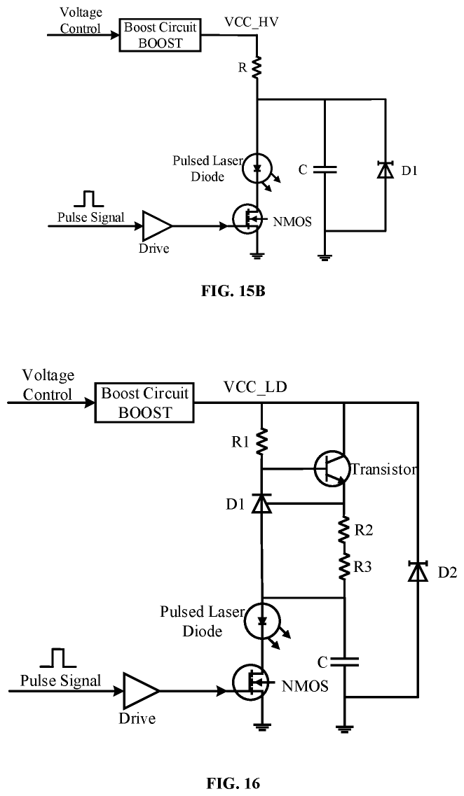

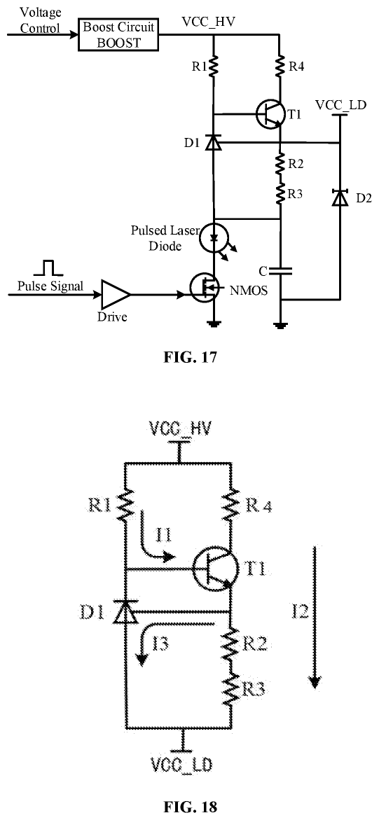

In some embodiments, the light emitting circuit may be as shown in FIG. 16. The light emitting circuit includes a power supply, a light source, a control circuit, and an energy storage circuit. The power supply is VCC_LD, as the energy supply of the light source. The light source is a pulsed laser diode. The control circuit includes a driving circuit and a switching circuit NMOS. The energy storage circuit includes an energy storage circuit and a charging circuit. The two energy storage circuits include resistors R2, R3, and a capacitor C. The energy storage circuit includes a capacitor C. The charging circuit includes resistors R2 and R3, and the charging circuit further includes a current limiting circuit and a voltage limiting circuit. The current limiting circuit includes R1, a voltage calibration source D1, and a transistor, which can protect the current on R2 and R3 from exceeding the rated power value of the resistor, and prevent excessive use and heating failure. The voltage limiting circuit includes D2, which can protect the VCC_LD from exceeding the designed limit value.

In this embodiment, the voltage control signal can set the output value of the boost circuit BOOST, thereby adjusting the working voltage of VCC_LD of the laser diode. When the pulse signal is low, the MOS tube may be turned off, and the laser diode may also be turned off. At this time, the capacitor C may be charged through the resistors R2 and R3 until the capacitor value is close to VCC_LD. When the pulse signal is high, the drive may output high voltage and high current, and quickly turn on the MOS tube. The capacitor C may be discharged through the laser diode and the MOS tube, such that the laser diode can be turned on and emit light.

In this embodiment, the emission power of the laser diode may be related to the amount of charge in the capacitor. When the output current of the capacitor is lower than the threshold current of the laser diode, the laser diode may stop emitting light. Since the light-emitting power and light-emitting time of the laser diode may only be related to the capacitor C, even if there is a bug in the software and the pulse width of the pulse signal is too large, at this time, the MOS tube has been turned on for a long time, but luminous power of the laser diode may be mainly related to the amount of charge of the capacitor, and may not be related to the pulse signal. Therefore, after one light emission, the amount of capacitor charge may not be enough to excite the diode to emit light, even if the MOS tube is turned on, it will not continue to emit light. When the MOS tube fails and is directly short-circuited, similar to having a bug in the software, after the laser diode emits light once, it will not continue to emit light. Therefore, this embodiment can improve the situation of the diode output exceeding the safety value caused by the first and second failure described above. In addition, this embodiment can also improve the situation of faulty power supply and VCC_LD being too high. At this time, the Zener or TVS tube D2 can be turned on to protect VCC_LD from exceeding the design limit value. Resistor R2 or R3 may fail and short-circuit. If it is a single failure, since the two resistors are connected in series, even if one of them fails, the circuit will still work normally. At this time, the charging time of the capacitor C will be reduced without affecting the amount of charge of the capacitor C, thereby ensuring that the laser emission does not change. This embodiment makes the light emitting device more reliable, thereby preventing the output of the light emitting device from exceeding the safety value due to malfunction.

In some embodiments, the light emitting device may be as shown in FIG. 17. FIG. 17 includes two power supply circuits VCC_LD and VCC_HV, where VCC_HV is connected to the laser diode, and VCC_LD is connected to the voltage limiting circuit D2 and the voltage reference source D1. The first end of the transistor in the current limiting circuit is connected to VCC_HV through a resistor R4, and other components and contents that are identical as those in the previous embodiment will not be repeated here.

When one of the following failure occurs in the system, the present disclosure may be used to protect the luminous power or radiation of the laser diode from exceeding the rated power and the rated radiation.

(1) There is a bug in the software and the pulse width of the pulse signal is too large. At this time, the MOS tube has been turned on for a long time, but luminous power of the laser diode may be mainly related to the amount of charge of the capacitor, and may not be related to the pulse signal. Therefore, after one light emission, the amount of capacitor charge may not be enough to excite the diode to emit light, even if the MOS tube is turned on, it will not continue to emit light

(2) The MOS tube fails and is directly short-circuited, similar to having a bug in the software, after the laser diode emits light once, it will not continue to emit light

(3) The power supply is faulty and VCC_LD is too high. At this time, the Zener or TVS tube D2 can be turned on to protect VCC_LD from exceeding the design limit value.

(4) Various parts of the circuit have the possibility of failure or short-circuit. The present disclosure can ensure the safety value of the light emitting device for various failure or short-circuit conditions, which will be described in detail below.

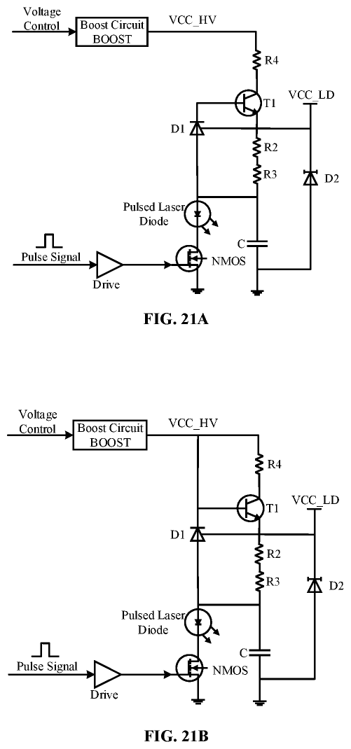

As shown in FIG. 21A, if the resistor R1 fails and opens, the transistor T1 is cut off, the system does not work, such that the laser diode may not emit light. As shown in FIG. 21B, if R1 fails and short-circuits, the transistor T1 is normally conducted. Taking into account the protection of D1, the entire charging circuit may work normally without affecting the normal light emission of the laser diode.

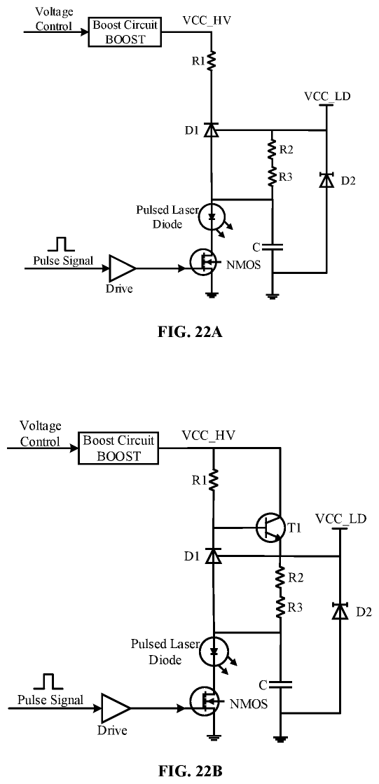

As shown in FIG. 22A, if R4 fails and opens, D1 is cut off, such that the charging circuit may not work and the laser diode may not emit light. As shown in FIG. 22B, if resistor R4 fails and short-circuits, the entire charging circuit may work normally without affecting the normal light emission of the laser diode.

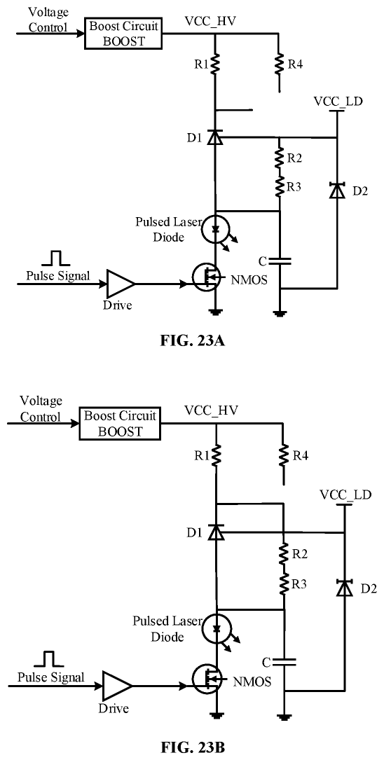

As shown in FIG. 23A, if T1 fails and opens, D1 is cut off, the system does not work, such that the laser diode may not emit light. As shown in FIG. 23B, if the base of the transistor T1 is short-circuited with the emitter, R1, D1, R2, and R3 can still form a normal charging circuit, which does not affect the normal light emission of the laser diode.

As shown in FIG. 24, if the three poles of the transistor T1 are short-circuited in pairs, the R1, R2, D1, R3, and R4 can still form a normal charging circuit, which does not affect the normal light emission of the laser diode.

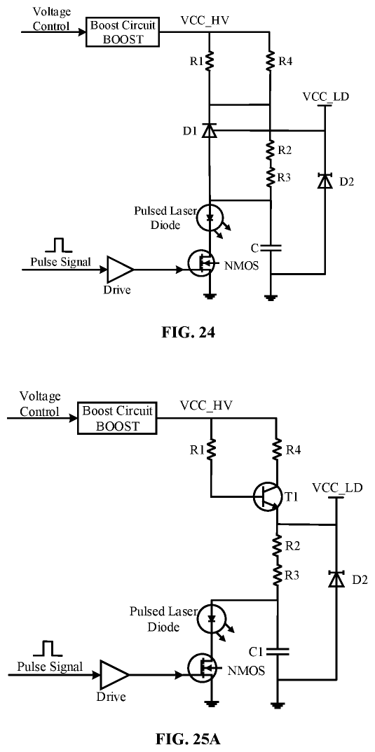

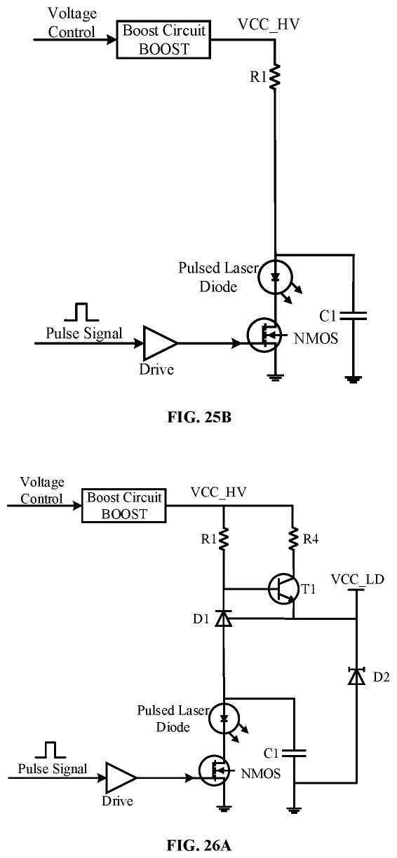

As shown in FIG. 25A, when the reference voltage stabilizing source D1 fails and opens, the voltage stabilizing circuit D2 can ensure that VCC_LD does not exceed the design value, thereby ensuring that the stored energy of the capacitor C does not exceed the limit value. As shown in FIG. 25B, when the reference voltage stabilizing source D1 fails and short-circuits, the charging circuit can be equivalent to only having R1, which can still meet the normal operation of the charging circuit.

As shown in FIG. 26A, when the resistor R2 or R3 fails and opens, the voltage stabilizing circuit D2 can ensure that VCC_LD does not exceed the design value, thereby ensuring that the stored energy of the capacitor C does not exceed the limit value. As shown in FIG. 26B, when the resistor R2 or R3 fails and short-circuits, if it is only a single failure, since the two resistors are connected in series, even if one of the two resistors fails, the circuit may still work normally without affecting the charge of the capacitor C, thereby ensuring the laser emission power does not change.

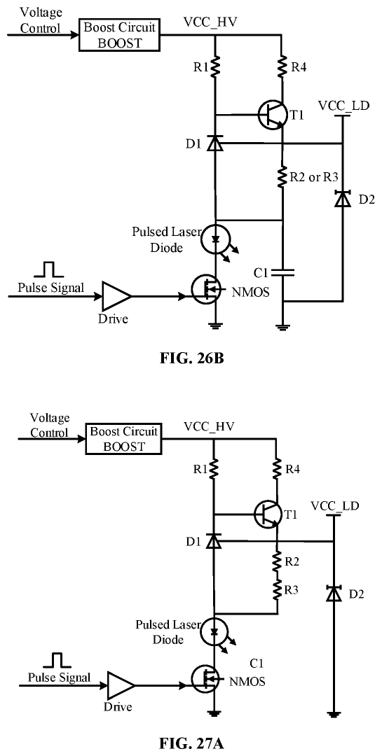

As shown in FIG. 27A, when the energy storage circuit C fails and opens, and the MOS tube is turned on, the voltage difference of the laser diode may be instantly reduced to 0V, and it may not be turned on and emit light. As shown in FIG. 27B, when the energy storage circuit C fails and short-circuits, both ends of the laser diode are both GND and cannot be turned on to emit light.

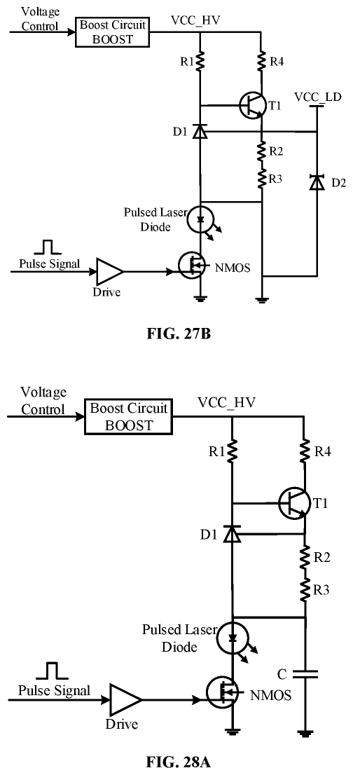

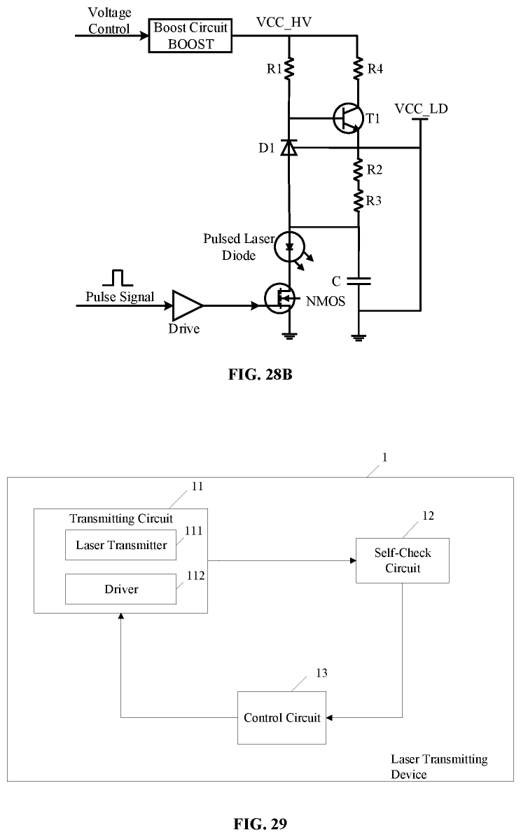

As shown in FIG. 28A, when the voltage stabilizing circuit D2 fails and opens, the charging circuit is designed to ensure that the stored energy of the capacitor C does not exceed the designed limit value. As shown in FIG. 28B, when the voltage stabilizing circuit D2 fails and short-circuits, D1 is cut off, and the charging circuit does not work.

In some embodiments, resistors R1, R2, R3, and R4, transistor T1, voltage stabilizing source D1 may be the charging circuit; and capacitor C may be the energy storage circuit; and D2 may be the voltage stabilizing circuit.

The core of the charging circuit may be the resistors R2 and R3, and the other circuits are provided to limit the current of R2 and R3 to protect the charging circuit. As shown in FIG. 18, under normal circumstances, the current I1 through R1 can turn on the transistor, such that the current 12 can flow through the emitter and the collector of the transistor T1. After passing through R3 and R4, if VCC_HV is set too large, then 12 increases, and the voltage drop between the resistors R3 and R4 increases. When the voltage drop increases to a certain threshold, D1 can be turned on, current I2 is shunted, and current I3 flows through the voltage reference source D1 to ensure that the current flowing through R2 and R3 does not exceed the rated value.

The charging circuit is not limited to the foregoing implementation, other implementations are provided below.

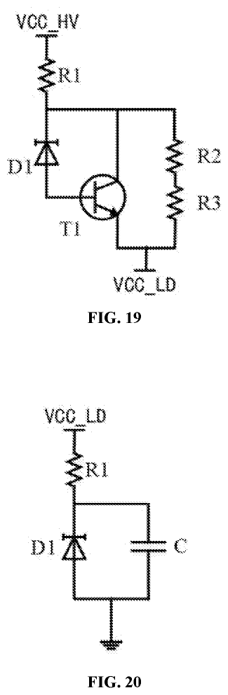

In some embodiments, the charging circuit may be based on the Zener diode D1 and the transistor T1, as shown in FIG. 19. Even when VCC_HV changes, it can be ensured that the voltage drop of R2 and R3 is stable at the design value, then there may be corresponding restrictions on the energy storage circuit to ensure the energy storage of the capacitor C.

The voltage stabilizing circuit is a redundant design to ensure that the voltage drop of the energy storage circuit C does not exceed the design value. The voltage stabilizing circuit can also be implemented in other ways, as shown in FIG. 20. If the voltage is too high, the Zener diode T1 can be turned on, thereby ensuring that the voltage drop of the capacitor C does not exceed the design value, and ensuring the voltage across the capacitor C.

As described above, the failure or short circuit of each element will not cause the output of the light emitting device to exceed the safety value. Therefore, the circuits described above can effectively ensure that the output of the light emitting device meets human eye safety regulations.

Compared with conventional technology, the light emitting device provided by the present disclosure can achieve a laser emitting technical solution that meets human eye safety regulations. When a single failure occurs in the system, the circuit in the above device can ensure that the laser radiation value does not exceed the safety value, thereby ensuring the safety of the laser device.

In some application scenarios (e.g., in lidar, optical fiber communication, etc.), laser diodes are used as signal sources, and based on specific applications, laser signals with a specific range of wavelengths and optical power are transmitted. In order to ensure good system performance, the characteristics of the laser must remain stable. However, under the premise of not changing the laser drive circuit, the optical power of the laser diode can shift as the ambient temperature changes. In addition, the laser diode or drive circuit may fail during use. An embodiment of the present disclosure further provides a light emitting device, which can detect the emission power or emission energy of the laser in real time.

FIG. 29 is a schematic block diagram of the laser transmitting device 1 according to an embodiment of the present disclosure. The light emitting device 1 includes a transmitting circuit 11, a self-check circuit 12, and a control circuit 13. The transmitting circuit 11 includes a laser transmitter 111 and a driver 112, and the laser transmitter 111 may be configured to emit a laser pulse signal under the drive of the driver 112. The self-check circuit 12 may be configured to detect the emission energy or the emission power of the laser pulse signal transmitted by the transmitting circuit 11. The control circuit 13 may be configured to adjust the emission power of the transmitting circuit 11 when the emission energy or the emission power of the laser pulse signal changes based on a detection result of the self-check circuit 12, such that the power of the laser pulse signal transmitted by the transmitting circuit 11 can be kept within a preset range; or, the control circuit 13 may be configured to determine whether to turn off the transmitting circuit 11 based on the detection result of the self-check circuit.

In some embodiments, in can be understood that the self-check circuit detecting the emission energy or the emission power of the laser pulse signal may include detecting the emission energy of the laser pulse signal and then converting it into the emission power, or detecting the emission power of the laser pulse signal and the converting it into the emission energy; and adjusting the emission power of the transmitting circuit based on the change of the emission power or the emission energy.

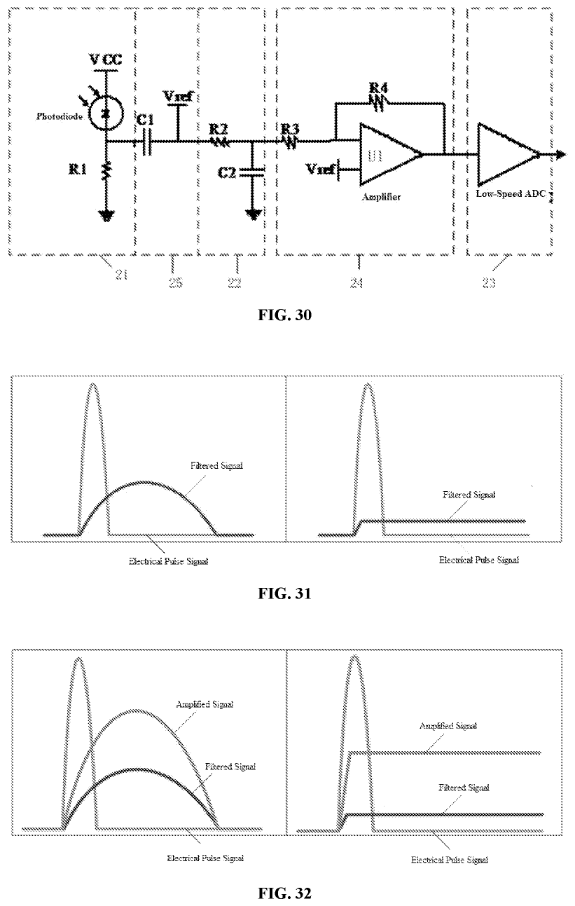

FIG. 30 is a schematic wiring diagram of a self-check circuit according to an embodiment of the present disclosure. As shown in FIG. 30, the self-check circuit includes a photoelectric conversion circuit 21 configured to receive the part of the laser pulse signal transmitted by the transmitting circuit and convert the part of the laser pulse signal into an electrical pulse signal; a pulse stretching circuit 22 configured to stretch the electrical pulse signal; and a sampling circuit 23 configured to sample the electrical signal after the stretching process.

It can be understood that the electrical signal after the stretching may be an electrical pulse signal or a level signal. In some embodiments, if the electrical signal after the stretching process is an electrical pulse signal, in some embodiments, the duty ratio of the electrical pulse signal after the stretching process may be greater than at least three times the duty cycle of the electrical pulse signal before the stretching process.

In some embodiments, the pulse stretching circuit 22 may include a RC filter circuit.

In some embodiments, the RC filter circuit may include a first-order RC filter circuit including a first resistor R2 and a first capacitor C2. One end of the first resistor R2 may receive the electrical signals from the photoelectric conversion circuit, the other end may be connected to one end of the first capacitor C2, and the other end of the first capacitor C2 may be grounded.

It can be understood that receiving the electrical signals from the photoelectric conversion circuit may include connecting the RC filter circuit directly to the photoelectric conversion circuit, or other circuits may be disposed between the RC filter circuit and the photoelectric conversion circuit.

In some embodiments, the self-check circuit may further includes an amplification circuit 24, and the amplification circuit 24 may be configured to amplify the signal output by the RC filter circuit.

In some embodiments, the amplification circuit 24 may include a proportional amplifying circuit including a first operational amplifier U1, a second resistor R3, and a third resistor R4. One end of the second resistor R3 may be connected to the RC filter circuit, and the other end may be connected to the negative input terminal of the first operational amplifier U1. The positive input terminal of the first operational amplifier U1 may be connected to the first reference power supply, and the output terminal may be connected to the sampling circuit. One end of the third resistor R4 may be connected to the negative input terminal of first operational amplifier U1, and the other end may be connected to the input terminal of the first operational amplifier U1.

In some embodiments, the self-check circuit may further includes a coupling circuit 25. The coupling circuit 25 may be configured to decouple the photoelectric conversion circuit 21 and the amplification circuit 24.

In some embodiments, the coupling circuit 25 may include a second capacitor C1. One end of the second capacitor C1 may receive the electrical signal from the photoelectric conversion circuit 21, and the other end may be connected to the RC filter circuit and the second reference power supply.

In some embodiments, the photoelectric conversion circuit 21 may include a seventh resistor R1. One end of the seventh resistor R1 may be connected to the anode of the photodiode, and the other end may be grounded. The cathode of the photodiode may be connected to the working power supply VCC.

Referring to FIG. 30, the working principle of the self-check circuit shown in FIG. 30 may be as follow. First, after the photodiode of the photoelectric conversion circuit 21 receives the light pulse signal transmitted by the laser diode in the laser transmitter, the photodiode is turned on. The connection point of the photodiode and the resistor R1 can generate an electrical signal, that is, the photoelectric conversion circuit can convert the light pulse signal into the electrical signal. Subsequently, after the first-order RC filter circuit including the resistor R2 and the capacitor C2, the electrical signal can be stretched to obtain a substantially DC or low-frequency signal, and the waveform may be as shown in FIG. 31. In some embodiments, the waveform stretched by the RC filter circuit depends on the time constant τ=R2*C2 of the RC filter circuit. The smaller the value of the time constant τ, the smaller the stretched pulse width. Next, the filtered electrical signal can be amplified by a proportional amplifier. In some embodiments, the ratio of the resistors R3 and R4 in the proportional amplifier may be used to adjust the amplification factor. The specific amplification factor may depend on the design needs and the actual conditions. The amplified electrical signal (i.e., the electrical signal for sampling) may be as shown in FIG. 32. Finally, the electrical signal passing through the proportional amplifier can be sampled.

In practical applications, lasers are often driven by high frequency and narrow pulses. Therefore, if the ADC sampling is used to obtain the laser emission power, the ADC sampling rate is very high and the cost is expensive. However, the present disclosure uses RC filtering to broaden the high-frequency narrow pulse into a low-frequency or even nearly DC signal, which is amplified by an amplifier, and then a low sampling rate ADC can be used for sampling, thereby greatly reducing the cost of power detection.

In addition, considering that the duty cycle of the laser pulse is very small, the DC or low-frequency signal voltage obtained directly after RC filtering may be very small, and it may be difficult to directly amplify the signal through a general amplifier. Therefore, it is also possible to choose to AC-couple the electrical signal output by the photoelectric conversion circuit to the second reference power supply through the capacitor C1 in the coupling circuit 25, and then amplify the electrical signal by an amplifier. Thereby realizing the low-speed ADC sampling signal value, and the capacitor C1 can also play the role of isolating the front and rear circuits. It should be noted that the coupling circuit may be optional based on the needs.

In some embodiments, the self-check circuit may include a photoelectric conversion circuit configured to receive the part of the laser pulse signal transmitted by the transmitting circuit and convert the part of the laser pulse signal into an electrical pulse signal; a peak hold circuit configured to hold the peak value of the electrical pulse signal; and a sampling circuit configured to sample the peak value of the electrical pulse signal held by the peak hold circuit. The self-check circuit in this embodiment is different from the self-check circuit described in FIG. 30 in that the sample peak hold circuit replaces the pulse stretch circuit described in the FIG. 30.

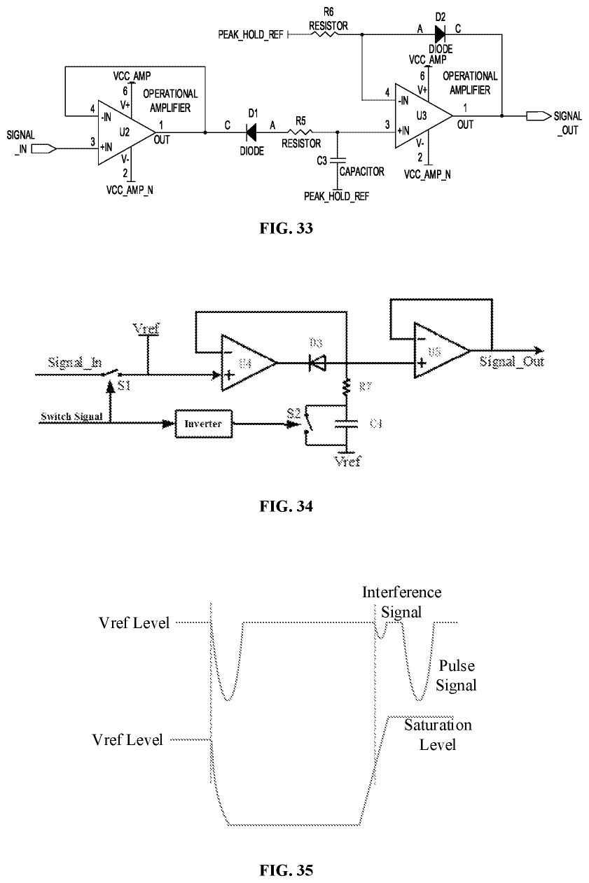

FIG. 33 is a first wiring diagram of a peak hold circuit according to an embodiment of the present disclosure. As shown in FIG. 33, the peak hold circuit includes a first diode D1, a fourth resistor R5, and a first energy storage circuit C3, where one end of the first diode can receive the electrical signal from the photoelectric conversion circuit, the other end of the first diode D1 is connected to one end of the fourth resistor R5, and the other end of the fourth resistor R5 is connected to one end of the first energy storage circuit C3, and outputs a signal to the sampling circuit. The other end of the first energy storage circuit C3 is connected to a third reference power supply.

FIG. 34 is a second wiring diagram of the peak hold circuit according to an embodiment of the present disclosure. As shown in FIG. 34, the peak hold circuit includes a second diode D3, a fifth resistor R7, and a second energy storage circuit C4. One end of the second diode D3 can receive the electrical signal from the photoelectric conversion circuit, and the other end of the second diode D3 and one end of the fifth resistor R7 can output a signal to the sampling circuit. The other end of the fifth resistor R7 is connected to one end of the second energy storage circuit C4, and the other end of the second energy storage circuit C4 is connected to a fourth reference power supply.

In some embodiments, the self-check circuit may include a first decoupling circuit positioned between the photoelectric conversion circuit and the peak hold circuit. The first decoupling circuit may be configured to decouple the photoelectric conversion circuit and the peak hold circuit.

In some embodiments, the first decoupling circuit may include a second operational amplifier U2. The positive input terminal of the second operational amplifier U2 may receive the electrical signal from the photoelectric conversion circuit, the negative input terminal of the second operational amplifier U2 may be connected to the output terminal of the second operational amplifier U2, and the output terminal of the second operational amplifier U2 may be connected to the peak hold circuit.

In some embodiments, the self-check circuit may include a third operational amplifier U4. The positive input terminal of the third operational amplifier U4 may receive the electrical signal from the photoelectric conversion circuit, and the negative input terminal of the third operational amplifier U4 may be connected to one end of the second diode and the fifth resistor. The output terminal of the third operational amplifier U4 may be connected to the other end of the second diode.

In some embodiments, the peak hold circuit may include a second decoupling circuit connected between the sampling circuit and the peak hold circuit, or after the sampling circuit. The second decoupling circuit may be configured to decouple the circuits before and after the second decoupling circuit.

In some embodiments, the second decoupling circuit may include the fourth operational amplifier U3, a sixth resistor R6, and a third diode D2. The positive input terminal of the fourth operational amplifier U3 may be connected to the peak hold circuit or the sampling circuit. The negative input terminal of the fourth operational amplifier U3 may be connected to one end of the sixth resistor R6 and one end of the third diode D2. The other end of the sixth resistor may be connected to a sixth reference power supply, and the other end of the third diode may be connected to the output terminal of the fourth operational amplifier U3. Alternatively, the second decoupling circuit may include a fifth operational amplifier U5. The positive input terminal of the fifth operational amplifier U5 may be connected to the peak hold circuit or the sampling circuit. The negative input terminal of the fifth operational amplifier U5 may be connected to the output terminal of the fifth operational amplifier U5.

Referring to FIG. 33, the working principle of the peak hold circuit may be as follow. First, the output signal Signal_in of the photoelectric conversion circuit is input to the positive input terminal of the operational amplifier U2. The negative input terminal of the operational amplifier U2 is connected to the output terminal of the operational amplifier U2 to form a voltage follower to decouple the photoelectric conversion circuit and the peak hold circuit. The output signal of the output terminal of the operational amplifier U2 may be the same as the output signal Signal_in of photoelectric conversion circuit. Next, the output terminal of the operational amplifier U2 can output a signal. When the signal rises or falls to cause the voltage across the diode exceed the threshold voltage of the diode D1, the diode D1 can be turned on, and the output signal of the operational amplifier US can charge the capacitor C3 through the diode D1 and the resistor R5. At this time, the voltage waveform of the capacitor C3 can change with the output signal of the operational amplifier U2, and the voltage waveform can rise or fall after the peak value. When the voltage across the diode is less than the threshold voltage of the diode D1, the diode D1 can be turned off, and the capacitor C3 will no longer be charged. In this process, the voltage waveform of the capacitor C3 can detect and maintain the peak value of the output signal of the operational amplifier U2. Subsequently, the electrical signal of the capacitor C3 can be output to the positive input terminal of the operational amplifier U3. The negative input terminal of the operational amplifier U3 is connected to one end of the resistor R6 and one end of the diode D2. The other end of the resistor R6 is connected to a sixth reference power supply. The other end of the diode D2 is connected to the output terminal of the operational amplifier U3. The operational amplifier U3, resistor R6, and diode D2 form a second decoupling circuit, that is, another voltage follower to decouple the peak hold circuit and other circuits. It can be understood that the second decoupling circuit positioned after the peak hold circuit may also be positioned after the sampling circuit.

The diode D2 in FIG. 33 is outside the feedback loop of the operational amplifier U1, and the peak value maintained by the capacitor C1 may include a voltage drop relative to Signal_in. In order to eliminate this voltage drop, it may be needed to ensure that the voltage drop of the diode D2 is the same as the voltage drop of the diode D1. That is, diodes D2 and D1 need to be the same to ensure that the peak value maintained by Signal_out is consistent with Signal_in. When the accuracy requirements are met, the peak hold circuit described above is not an issue, but when the accuracy requirements are very high, and there are individual differences in electronic components, it is difficult to ensure that the voltages on the diodes D2 and D1 are identical.

Therefore, an embodiment of the present disclosure further provides another middle peak detection circuit. Referring to FIG. 34, the working principle of the peak detection circuit shown in FIG. 34 will be described below.

First, the output signal Signal_in of the photoelectric conversion circuit is input to the positive input terminal of the operational amplifier U4, the negative input terminal of the operational amplifier U4 is connected to one end of the diode D3, and the other end of the diode D3 is connected to the output terminal of the operational amplifier U2 to decouple the photoelectric conversion circuit and the peak hold circuit. Then, similarly, the diode D3 can be turned on, and the output signal of the operational amplifier U4 can charge the capacitor C4 through the diode D3 and the resistor R7. At this time, the voltage waveform of the capacitor C4 can change with the output signal of the operational amplifier U4, and the voltage waveform can rise or fall after the peak value. When the voltage across the diode is less than the threshold voltage of the diode D3, the diode D3 can be turned off and stop charging the capacitor C4. In this process, the voltage waveform of the capacitor C4 can detect and maintain the peak value of the output signal of the operational amplifier U2. In some embodiments, the diode D3 may be placed in the feedback loop of the operational amplifier U4. As such, the voltage of the positive input terminal of the operational amplifier U5 can be consistent with the negative input terminal voltage of the operational amplifier U4, thereby ensuring that the peak value of the output signal Signal_out of the operational amplifier U5 is consistent with the peak value of the output signal Signal_in of the photoelectric conversion circuit, improving the mismatch of the diodes of the peak hold circuit in the previous embodiment, such that the second decoupling circuit after the peak hold circuit does not need a diode or may be the same as the diode in the first decoupling circuit described above. Subsequently, the connecting end of the diode D3 and the resistor R7 can output a signal to the second decoupling circuit. The second decoupling circuit may adopt the circuit structure of the first or second decoupling circuit in the previous embodiment, which will not be repeated here. It can be understood that the second decoupling circuit positioned after the peak hold circuit may also be positioned after the sampling circuit.

It should be noted that in the embodiments of the present disclosure, the first decoupling circuit, the peak detection circuit, and the second decoupling circuit may all comprise at least one form. It can be understood that the three circuits can be used based on design needs and actual application conditions, as well as cooperate with each other. Therefore, in addition to the circuit arrangement described in the accompanied drawings, other changes in the coordination arrangement of the three circuits are also within the scope of the present disclosure.

In addition, in the conventional peak hold circuits, only the switching signal is added at both ends of the holding capacitor to release the charge. However, when an unexpected situation occurs, such as when the charge is released, since the positive input voltage of the operational amplifier U4 is Vref and the negative input has not recovered to the Vref voltage, at this time, the signal waveforms of the positive and negative input terminals of the operational amplifier U4 as shown in FIG. 35, if there is a weak interference signal input at the positive input terminal, the operational amplifier U4 will enter a deeply saturated state, and the circuit cannot respond, causing the system to fail to work normally. Therefore, the present disclosure adds a switch S1 to the positive input terminal of the operational amplifier U4 to prevent interference from other signals.

In some embodiments, the self-check circuit may further include a reset circuit for resetting the peak hold circuit.

In some embodiments, the reset circuit may include a first switch, a second switch, and an inverter. One end of the first switch can receive the electrical signal of the photoelectric conversion circuit, and the other end of the first switch may be connected to the peak hold circuit or the first decoupling circuit. The second switch may be connected to two ends of the first storage circuit or the second storage circuit. A first switch control signal can control the on and off of the first switch, and after passing through the inverter, a second switch control signal can be generated to control the on and off of the second switch, such that the on and off states of the first switch and the second switch can be reversed.

Referring to FIG. 34, the reset circuit includes switches S1 and S2, and an inverter. The switch S2 is connected in series between the input signal and the positive input terminal of the operational amplifier U4. The switch S2 is connected in parallel with the two ends of the capacitor C4 to control the switch S1 by the switch signal, and the switch S2 is controlled after the inverter, thereby ensuring that the switching state of the switches S1 and S2 are opposite. When S2 is closed, the capacitor C4 discharges the charge. At this time, S1 is opened to ensure that weak interference signals cannot enter the non-inverting input of U1. When the entire amplifier system enters a new steady state, S2 opens and S1 closes. At this time, the system can normally respond to the input pulse signal.

In some embodiments, the control circuit 13 may be configured to adjust the emission power of the transmitting circuit based on the detection result of the self-check circuit, such that the power of the laser pulse signal transmitted by the transmitting circuit can be kept within a predetermined range.

In some embodiments, the control circuit 13 may be configured to adjust the emission power of the transmitting circuit or turning off the transmitting circuit based on the sampling voltage value of the sampling circuit.

In some embodiments, when the sampling voltage value exceeds a predetermined voltage upper limit, the control circuit may reduce the gain of the transmitting circuit; and/or, when the sampling voltage value is zero or almost zero, the transmitting circuit may be turned off.

In some embodiments, the laser transmitting device may be configured to store a corresponding relationship between the emission power of the transmitting circuit and the sampling value of the sampling circuit, and the control circuit may be configured to adjust the emission power of the transmitting circuit based on the corresponding relationship.

It can be understood that the stored corresponding relationship between the emission power of the transmitting circuit and the sampling value of the sampling circuit may be a corresponding relationship between the voltage of the transmitting circuit and the sampling value, or a corresponding relationship between the gain and the sampling value, or a corresponding relationship between other parameters that can affect the emission power of the transmitting circuit when it is adjusted and the sampling value.

More specifically, in actual application scenarios, the laser emission frequency may be at a constant value for a certain period of time. At this time, the peak value of the stretched pulse and the peak value of the narrow pulse may have a one-to-one correspondence. If the stretching circuit directly stretches the pulse width to a DC signal, then the amplitude of the DC signal and the energy value of the narrow pulse may have a one-to-one correspondence. Therefore, for different emission powers, if amplified by the same multiple, the DC signal amplitude or the peak value of the stretched pulse will be different. The greater the emission power, the greater the ADC sampling voltage value, such that based on data fitting, the mapping relationship between the emission power and the ADC sampling value can be obtained. Then the emission power can be inversely deduced based on the ADC sampling voltage value, for example, when the ambient temperature rises, the emission power decreases accordingly. When the power detection circuit finds that the power drops, it can feed back to the system to increase the emission voltage, and ultimately maintain the stability of the emission power.

It should be noted that in the embodiments of the present disclosure, the first reference power supply to the sixth reference power supply are used to distinguish the reference power supplies, where the levels of the first reference power supply to the sixth reference power supply may be the same or different.

It should also be noted that in the embodiments of the present disclosure, the first resistor to the seventh resistor include at least one resistor and its series-parallel form, and the first capacitor to the second energy storage circuit include at least one capacitor and its series parallel form.

It should also be noted that in the embodiments of the present disclosure, the first diode to the third diode is set based on the positive or negative pulse signal of the laser.

Compared with the conventional technology, the laser transmitting device provided by the present disclosure can detect the power of the transmitted laser pulse signal through a self-check circuit, feedback the relative change in power or the failure of laser emission in time, and determine to adjust or turn off the laser pulse signal based on the feedback detection result, thereby ensuring that the laser emission power remains constant in different scenarios and realizing the function of system failure self-check.

The various circuits provided by the various embodiments of the present disclosure can be applied to a distance measuring device, and the distance measuring device may be an electronic device such as a lidar and a laser distance measuring device. In one embodiment, various embodiments of the present disclosure provide a distance measuring device for sensing external environmental information, such as distance information, orientation information, reflection intensity information, speed information, etc. of targets in the environment. In one embodiment, the distance measuring device can detect the distance from an object to be measured to the distance measuring device by measuring the time of light propagation between the distance measuring device and the object to be measured, that is, the time-of-flight (TOF). Alternatively, the distance measuring device may also detect the distance between the object to be detected and the distance measuring device through other technologies, such as a distance measuring method based on phase shift measurement or a distance measuring method based on frequency shift measurement, which is not limited in the embodiments of the present disclosure.

For ease of understanding, the working process of distance measurement will be described by an example in conjunction with a distance measuring device 100 shown in FIG. 13.

As shown in FIG. 13, the distance measuring device 100 includes a transmitting circuit, a receiving circuit, a sampling circuit (TDC), and an arithmetic circuit. In some embodiments, the transmitting circuit may be the transmitting circuit described in the above embodiment, and the sampling circuit may include the amplification circuit described in the above embodiment.

The transmitting circuit may emit a light pulse sequence (e.g., a laser pulse sequence). The receiving circuit may receive the light pulse sequence reflected by the object to be detected, and perform photoelectric conversion on the light pulse sequence to obtain an electrical signal. After the electrical signal is processed, it may be output to the sampling circuit. The sampling circuit may sample the electrical signal to obtain a sampling result. The arithmetic circuit may determine the distance between the distance measuring device and the object to be detected based on the sampling result of the sampling circuit.

In some embodiments, the distance measuring device may also include a control circuit, the control circuit may be used to control other circuits. For example, the control circuit may control the working time of each circuit and/or set the parameters of each circuit.

It can be understood that although the distance measuring device shown in FIG. 13 includes a transmitting circuit, a receiving circuit, a sampling circuit, and an arithmetic circuit, the embodiments of the present disclosure are not limited thereto. The number of any one of the transmitting circuit, the receiving circuit, the sampling circuit, and the arithmetic circuit may also be two or more.

In some embodiments, in addition to the circuits shown in FIG. 13, the distance measuring device may further include a scanning module. The scanning module may be used to change the propagation direction of the laser pulse sequence transmitted by the transmitting circuit and emit it.

In some embodiments, a module including the transmitting circuit, the receiving circuit, the sampling circuit, and the arithmetic circuit or a module including the transmitting circuit, the receiving circuit, the sampling circuit, the arithmetic circuit, and the control circuit can be referred to as a distance measurement module. The distance measurement module may be independent of other modules, such as the scanning module.

A coaxial optical path can be used in the distance measuring device. That is, the light beam transmitted by the distance measuring device and the reflected light beam can share at least part of the optical path in the distance measuring device. Alternatively, the distance measuring device may also use an off-axis optical path. That is, the light beam transmitted by the distance measuring device and the reflected light beam can be transmitted along different optical paths in the distance measuring device.

The distance measuring device 100 includes an optical transceiver 121. The optical transceiver 121 includes a light source 103 (including the transmitting circuit described above), a collimating element 104, and a detector 105 (which may include the receiving circuit, the sampling circuit, and the arithmetic circuit described above), and an optical path changing element 106. The optical transceiver 121 may be used to emit light beams, receive returned light, and convert the returned light into electrical signals. The light source 103 may be used to emit a light beam. In some embodiments, the light source 103 may emit a laser beam. In some embodiments, the laser beam transmitted by the light source 103 may be a narrow-bandwidth beam with a wavelength outside the visible light range. The collimating element 104 may be disposed on the exit light path of the light source, and configured to collimate the light beam transmitted from the light source 103 and collimate the light beam transmitted from the light source 103 into parallel light. The collimating element 104 may also be configured to condense at least a part of the returned light reflected by the object to be detected. The collimating element 104 may be a collimating lens or other elements capable of collimating light beams.

In the embodiment shown in FIG. 13, the optical path changing element 106 may combine the transmitting light path and the receiving light path in the distance measuring device before the collimating element 104, such that the transmitting light path and the receiving light path can share the same collimating element, making the light path more compact. In other embodiments, the light source 103 and the detector 105 may use respective collimating elements, and the optical path changing element 106 may be disposed behind the collimating elements.

In the embodiment shown in FIG. 13, since the beam divergence angle of the light beam transmitted by the light source 103 is relatively small, and the beam divergence angle of the returned light received by the distance measuring device is relatively large, the optical path changing element 106 may use a small reflector to combine the transmitting light path and the receiving light path. In other embodiments, the optical path changing element 106 may also be a reflector with a through hole, where the through hole can be used to transmit the transmitted light of the light source 103, and the reflector may be used to reflect the returned light to the detector 105. In this way, the chances of the support of the small reflector blocking the returned light can be reduced.

In the embodiment shown in FIG. 13, the optical path changing element 106 deviates from the optical axis of the collimating element 104. In other embodiments, the optical path changing element 106 may also be positioned on the optical axis of the collimating element 104.

The distance measuring device 100 further includes a scanning module 102. The scanning module 102 may be positioned on the exit light path of the optical receiver 100. The scanning module 102 may be used to change the transmission direction of a collimated light beam 119 transmitted by the collimating element 104, project the collimated light beam 119 to the external environment, and project the returned light to the collimating element 104. The returned light can be collected on the detector 105 via the collimating element 104.

In some embodiments, the scanning module 102 may include one or more optical elements, such as lens, mirrors, prisms, optical phased array, or any combination of the above optical elements. In some embodiments, the plurality of optical elements of the scanning module 102 may rotate around a common axis 109, an each rotating optical element may be used to continuously change the propagation direction of the incident light beam. In some embodiments, the plurality of optical elements of the scanning module 102 may rotate at different speeds. In other embodiments, the plurality of optical elements of the scanning module 102 may rotate at substantially the same speed.

In some embodiments, the plurality of optical elements of the scanning module 102 may also rotate around different axes. In some embodiments, the plurality of optical elements of the scanning module 102 may also rotate in the same direction or in different directions, or vibrate in the same direction or different directions, which is not limited in the embodiments of the present disclosure.

In some embodiments, the scanning module 102 may include a first optical element 114 and a driver 116 connected to the first optical element 114. The driver 116 can be used to drive the first optical element 114 to rotate around the rotation axis 109 such that the first optical element 114 can change the direction of the collimated light beam 119. The first optical element 114 can project the collimated light beam 119 to different directions. In some embodiments, the angle between the direction of the collimated light beam 119 changed by the first optical element 114 and the rotation axis 109 may change as the first optical element 114 rotates. In some embodiments, the first optical element 114 may include a pair of opposite non-parallel surface through which the collimated light beam 119 can pass. In some embodiments, the first optical element 114 may include a prism whose thickness may vary along one or more radial directions. In some embodiments, the first optical element 114 may include a wedge-angle prism to refract the collimated light beam 119. In some embodiments, the first optical element 114 may be coated with an anti-reflection coating, and the thickness of the anti-reflection coating may be equal to the wavelength of the light beam transmitted by the light source 103, which can increase the intensity of the transmitted light beam.

In some embodiments, the scanning module 102 may further include a second optical element 115. The second optical element 115 may rotate around the rotation axis 109, and the rotation speed of the second optical element 115 may be different from the rotation speed of the first optical element 114. The second optical element 115 may be used to change the direction of the light beam projected by the first optical element 114. In some embodiments, the second optical element 115 may be connected to a driver 117, and the driver 117 can drive the second optical element 115 to rotate. The first optical element 114 and the second optical element 115 can be driven by different drivers, such that the rotation speed of the first optical element 114 and the second optical element 115 can be different, such that the collimated light beam 119 can be projected to different directions in the external space, and a larger spatial range can be scanned. In some embodiments, a controller 118 may be used to control the driver 116 and the driver 117 to drive the first optical element 114 and the second optical element 115, respectively. The rotation speeds of the first optical element 114 and the second optical element 115 may be determined based on the area and pattern expected to be scanned in actual applications. The driver 116 and the driver 117 may include motors or other driving devices.

In some embodiments, the second optical element 115 may include a pair of opposite non-parallel surfaces through which the light beam can pass. In some embodiments, the second optical element 115 may include a prism whose thickness may vary in one or more radial directions. In some embodiments, the second optical element 115 may include a wedge prism. In some embodiments, the second optical element 115 may be coated with an anti-reflection coating to increase the intensity of the transmitted light beam.

The rotation of the scanning module 102 may project light in different directions, such as directions 111 and 113. In this way, the space around the distance measuring device 100 can be scanned. When the light projected by the scanning module 102 hits an object to be detected 101, a part of the light may be reflected by the object to be detected 101 to the distance measuring device 100 in a direction opposite to direction 111. The scanning module 102 can may receive a returned light 112 reflected by the object to be detected 101 and project the returned light 112 to the collimating element 104.

The collimating element 104 may converge at least a part of the returned light 112 reflected by the object to be detected 101. In some embodiments, an anti-reflection coating may be coated on the collimating element 104 to increase the intensity of the transmitted light beam. The detector 105 and the light source 103 may be disposed on the same side of the collimating element 104, and the detector 105 may be used to convert at least part of the returned light passing through the collimating element 104 into an electrical signal.

In some embodiments, the light source 103 may include a laser diode through which nanosecond laser light can be transmitted. For example, the laser pulse transmitted by the light source 103 ma last for 10 ns. Further the laser pulse receiving time may be determined, for example, by detecting the rising edge time and/or falling edge time of the electrical signal pulse to determine the laser pulse receiving time. In this way, the distance measuring device 100 may calculate the TOF using the pulse receiving time information and the pulse sending time information, thereby determining the distance between the object to be detected 101 and the distance measuring device 100.

In some embodiments, the distance and orientation detected by the distance measuring device 100 can be used for remote sensing, obstacle avoidance, surveying and mapping, modeling, navigation, and the like.

In some embodiments, the distance measuring device of the embodiments of the present disclosure may be applied to a movable platform. For example, the distance measuring device may be mounted to a main body of the movable platform. The movable platform can perform a measurement of an external environment through the distance measuring device. For example, the distance measuring device may be configured to measure a distance between the movable platform and an obstacle, which may be used for obstacle avoidance. As another example, the distance measuring device may be configured to perform a two-dimensional or three-dimensional survey of the external environment.

The technical terms used in the embodiments of the present disclosure are merely used to describe specific embodiments, but are not intended to limit the present disclosure. In this specification, singular forms “one”, “this”, and “the” are intended to simultaneously include a plural form, unless otherwise specified in the context clearly. Further, the term “include” and/or “contain” used in this specification specifies presence of the features, entirety, steps, operations, elements and/or components, but does not exclude presence or addition of one or more of other features, entirety, steps, operations, elements, and/or components.

In the appended claims, the corresponding structures, materials, actions, and equivalent forms (if any) of all apparatuses or steps and function elements are intended to include any structure, material, or action that is used to perform the function with reference to other explicitly required elements. The descriptions of the present disclosure are provided for the purpose of the embodiments and the descriptions, but are not intended to be exhaustive or limit the present disclosure. Numerous modifications and variations will be apparent to those skilled in the art without departing from the scope of the present disclosure. The embodiments described in the present disclosure can better disclose the principles and practical applications of the present disclosure, and can enable those skilled in the art to understand the present disclosure.

The flowcharts described in the present disclosure are merely examples, and various modifications may be made to the drawings or the steps of the present disclosure without departing from the spirit of the invention. For example, these steps can be performed in a different order, or some steps can be added, deleted, or modified. A person skilled in the art can understand that all or part of the process of implementing the above embodiments, and equivalent changes made according to the claims of the present disclosure, still fall within the scope of the present disclosure.

What is claimed is:

1. An amplification circuit, comprising:
an operational amplifier; and
a clamping circuit being respectively connected to an input terminal and an output terminal of the operational amplifier for clamping an input signal of the amplification circuit to cause the input signal of the amplification circuit to fluctuate within a certain range to prevent the operational amplifier from generating a saturating output.

2. The amplification circuit of claim 1, wherein:
the clamping circuit includes a diode.

3. The amplification circuit of claim 2, wherein:
the diode is a Zener tube or a TVS tube.

4. The amplification circuit of claim 2, wherein:
the clamping circuit includes a voltage dividing resistor.

5. The amplification circuit of claim 2, wherein:
one end of the diode of the clamping circuit is connected to the input signal, and an other end of the diode of the clamping circuit is connected to the output terminal of the operational amplifier.

6. The amplification circuit of claim 5, wherein:
one end of the voltage dividing resistor is connected to a reference voltage, and an other end of the voltage dividing resistor is connected to the output terminal of the operational amplifier.

7. The amplification circuit of claim 6, wherein:
one end of the diode of the clamping circuit is connected to the input signal, and an other end of the diode of the clamping circuit is connected to the output terminal of the operational amplifier through one or more voltage dividing resistors.

8. The amplification circuit of claim 4, wherein:
the voltage dividing resistor includes two or more resistors.

9. The amplification circuit of claim 8, wherein:
the two or more resistors in the voltage dividing resistor are connected in series, a connecting end of the two or more resistors is connected to one end of the diode, an other end of one of the two or more resistors is connected to the reference voltage, and an other end of the two or more resistors is connected to the output terminal of the operational amplifier.

10. The amplification circuit of claim 1, wherein:
the operational amplifier is an inverting amplifier circuit or a forward amplifier circuit.

11. The amplification circuit of claim 1 further comprising:
a feedback circuit configured to adjust an amplification factor of the operational amplifier.

12. The amplification circuit of claim 11, wherein:
the feedback circuit includes one or more of a resistor, a diode, or a capacitor.

13. The amplification circuit of claim 12, wherein:
any diode or any capacitor of the feedback circuit is connected in parallel with a plurality of resistors of the feedback circuit.

14. The amplification circuit of claim 13, wherein:
the plurality of resistors in the feedback circuit are connected in series to reduce parasitic parameters on the plurality of resistors in the feedback circuit to achieve high bandwidth.

15. The amplification circuit of claim 14, wherein:
the feedback circuit includes three resistors, and the three resistors are connected in series, a first resistor of the three resistors being connected in parallel with the capacitor, a second resistor of the three resistors being connected in parallel with the diode, and a third resistor of the three resistors being connected in parallel with the diode.

16. A distance detection device, comprising:
a transmitting circuit configured to emit a light pulse sequence;
a photoelectric conversion circuit configured to sequentially receive a plurality of light pulse signals of a plurality of light pulses in the light pulse sequence transmitted by the transmitting circuit reflected by an object, and sequentially convert the plurality of received light pulse signals into a plurality of electrical pulse signals; and
an amplification circuit configured to receive the plurality of electrical pulse signals from the photoelectric conversion circuit, the operational amplifier including an operational amplifier and a clamping circuit, the clamping circuit being configured to sequentially clamp the plurality of electrical pulse signals, wherein
the plurality of electrical pulse signals are sequentially input to the operational amplifier for amplification after being clamped, and
the clamping circuit is configured to cause fluctuation of the plurality of electrical pulse signals to be within a certain range to prevent the operational amplifier from generating a saturating output.

17. The distance detection device of claim 16 further comprising:
a sampling circuit configured to sample the plurality of electrical pulse signals from the amplification circuit to obtain a sampling result; and
an arithmetic circuit configured to calculate a distance between the object and the distance measuring device based on the sampling result.

18. The distance detection device of claim 16, wherein:
there are two or more transmitting circuits, photoelectric conversion circuits, and amplification circuits;
the two or more transmitting circuits and the two or more photoelectric conversion circuits have a one-to-one correspondence, each photoelectric conversion circuit being configured to sequentially receive the plurality of light pulse signals of the plurality of light pulses in the light pulse sequence transmitted by the corresponding transmitting circuit reflected by the object; and
the two or more photoelectric conversion circuits and the two or more amplification circuits have a one-to-one correspondence, each amplification circuit being configured to sequentially receive the plurality of electrical pulse signals from the corresponding photoelectric conversion circuit.

19. The distance detection device of claim 16 further comprising:
a scanning module configured to change a transmission direction of the light pulse signal and emit the light pulse signal, the light pulse signal reflected by the object incident on the photoelectric conversion circuit after passing through the scanning module.

20. The distance detection device of claim 19, wherein:
the scanning module includes a driver and a prism with uneven thickness, the driving being configured to drive the prism to rotate to change the light pulse signal passing through the prism to emit in different directions.

21. The distance detection device of claim 19, wherein:
the scanning module includes two drivers, and two parallel prisms with uneven thickness, the two drivers being configured to drive the two prisms to rotate in opposite directions, the light pulse signal from the transmitting circuit passing through the two prisms to change the transmission direction to be transmitted.
